(19) United States
(12) Patent Application Publication
(10) Pub. No.: US 2015/0228498 A1
(43) Pub. Date: Aug. 13, 2015

(54) METHOD FOR MANUFACTURING ADHESIVE FILM FOR IMPRINTS AND METHOD FOR FORMING PATTERNS

(71) Applicant: FUJIFILM CORPORATION, Tokyo (JP)

(72) Inventors: Akiko HATTORI, Haibara-gun (JP); Tadashi OOMATSU, Haibara-gun (JP); Hirotaka KITAGAWA, Haibara-gun (JP); Yuichiro ENOMOTO, Haibara-gun (JP)

(73) Assignee: FUJIFILM CORPORATION, Tokyo (JP)

(21) Appl. No.: 14/696,535

(22) Filed: Apr. 27, 2015

Related U.S. Application Data
(63) Continuation of application No. PCT/JP2013/079492, filed on Oct. 31, 2013.

(30) Foreign Application Priority Data
Nov. 2, 2012 (JP) 2012-242404

(51) Int. Cl. H01L 21/308; C09J 133/14; C09J 7/02

(52) U.S. Cl. CPC H01L 21/3086; H01L 21/3081; H01L 21/3085; H01L 21/3088; C09J 7/02; C09J 133/14; C09J 2433/00

(57) ABSTRACT

To obtain a good pattern having a good profile of etched pattern. A method for manufacturing an adhesive film for imprints, the method comprising applying an adhesive composition for imprints in a base, and then rinsing the adhesive composition for imprints.

This application is a Continuation of PCT International Application No. PCT/JP2013/079492 filed on Oct. 31, 2013, which claims priority under 35 U.S.C. §119 (a) to Japanese Patent Application No. 2012-242404 filed on Nov. 2, 2012. The above application is hereby expressly incorporated by reference, in its entirety, into the present application.

### TECHNICAL FIELD

This invention relates to a method or manufacturing an adhesive film for imprints (may simply be referred to as “adhesive film”, hereinafter) used for improving adhesiveness between a photo-curable composition for imprints (may simply be referred to as “photo-curable composition”, hereinafter) and a substrate. This invention also relates to a method for forming a pattern using the adhesive film. This invention furthermore relates to a method for manufacturing a semiconductor device using the adhesive film, and such semiconductor device.

### DESCRIPTION OF THE RELATED ART

Imprint technology is a development advanced from embossing technology well known in the art of optical disc production, which comprises pressing a mold original with an embossed pattern formed on its surface (this is generally referred to as “mold”, “stamper” or “template”) against a resin to thereby accurately transfer the micropattern onto the resin through mechanical deformation of the resin. In this, when a mold is once prepared, then microstructures such as nanostructures can be repeatedly molded, and therefore, this is economical, and in addition, harmful wastes and discharges from this nanotechnology are reduced. Accordingly these days, this is expected to be applicable to various technical fields.

On the other hand, imprinting is known as a method of transferring a micro-pattern onto a photo-cured material, by allowing a curable composition to cure under photo-irradiation through a translucent mold or a translucent substrate, and then by separating the mold. The imprinting may be implemented at room temperature, so that it is applicable to the field of precision working typically for forming ultra-fine patterns such as semiconductor integrated circuit. In recent years, new trends in development of nano-casting based on combination of advantages of the both, and reversal imprinting capable of creating a three-dimensional laminated structure have been reported.

Applications listed below have been proposed for the imprinting.

A first application relates to that a geometry (pattern) per se obtained by molding is functionalized so as to be used as a nano-technology component, or a structural member. Examples of which include a variety of micro- or nano-optical component, high-density recording medium, optical film, and structural member of flat panel display.

A second application relates to building-up of a laminated structure by using a mold capable of simultaneously forming a micro-structure and a nano-structure, or by simple alignment between layers, and use of the laminated structure for manufacturing p-TAS (Micro-Total Analysis System) or biochip.

A third application relates to use of the thus-formed pattern as a mask through which a substrate is worked typically by etching. By virtue of precise alignment and a large degree of integration, this technique can replace the conventional lithographic technique in manufacturing of high-density semiconductor integrated circuit, transistors in liquid crystal display device, and magnetic material for composing next-generation hard disk called patterned medium. Approaches for implementing the imprinting in these applications have been becoming more active in recent years.

With progress of activities in the imprinting, there has been emerging a problem of adhesiveness between the substrate and the curable composition for imprints. In the imprinting, the curable composition for imprints is coated over the substrate, and is allowed to cure under photo-irradiation, while being brought into contact on the surface thereof with a mold, and then the mold is separated. In the process of separating the mold, the cured product may sometimes separate from the substrate, and unfortunately adhere to the mold. This is supposedly because the adhesiveness between the substrate and the cured material is smaller than the adhesiveness between the mold and the cured material. As a solution to this problem, there has been discussed an adhesive membrane obtainable by using an adhesive composition for imprints which enhances the adhesiveness between the substrate and the cured material (Patent Literature 1, Patent Literature 2).

### CITATION LIST

### Patent Literature

[Patent Literature 1] JP-A-2009-503139
[Patent Literature 2] JP-A-2011-508680

### SUMMARY OF THE INVENTION

### Technical Problem

The techniques described in Patent Literature 1 and Patent Literature 2 were, however, found to produce aggregates in the adhesive film for imprints, depending on materials and thickness. The aggregates were found to make the thickness of the adhesive film for imprints non-uniform. The adhesive film for imprints, if made non-uniform, may make the thickness of a resist film non-uniform, and may thereby degrade the profile of a finally obtainable etched pattern.

It is therefore an object of this invention to solve the above-described problems, and is to provide a method for manufacturing an adhesive film for imprints by which a good profile of the etched pattern is obtainable.

### Solution to Problem

After intensive studies conducted under such circumstances, the present inventors found out that, by rinsing the adhesive composition for imprints, the adhesive film for imprints may be suppressed from producing therein the aggregates, and thereby a good profile of etched pattern may be obtained. The findings led us to complete this invention.

More specifically, the problem was solved by a means <1> described below, and more preferably by means <2> to <18>.

<1> A method for manufacturing an adhesive film for imprints, the method comprising applying an adhesive composition for imprints in a base, and then rinsing the adhesive composition for imprints.
<2> The method for manufacturing an adhesive film for imprints of <1>, wherein the rinsing is followed by baking.
<3> The method for manufacturing an adhesive film for imprints of <1> or <2>, wherein the rinsing is effected by spin coating.
<4> The method for manufacturing an adhesive film for imprints of <3>, wherein, assuming a time range between a start and an end of rinsing as T, the base is spun at a smaller number of rotation (rpm) in a time range up to 0.005T to 0.3T after the start of rinsing, than in a time range 0.6T up to 0.95T before the end of rinsing.
<5> The method for manufacturing an adhesive film for imprints of any one of <1> to <4>, wherein the rinsing is conducted using a solvent having a boiling point of 50 to 180° C.
<6> The method for manufacturing an adhesive film for imprints of any one of <1> to <4>, wherein the rinsing is conducted using propylene glycol monomethyl ether acetate.
<7> The method for manufacturing an adhesive film for imprints of any one of <1> to <6>, wherein the rinsing is started within one hour after the adhesive composition for imprints is applied in the base.
<8> The method for manufacturing an adhesive film for imprints of any one of <1> to <7>, wherein the adhesive composition for imprints contains a polymerizable compound and a solvent.
<9> The method for manufacturing an adhesive film for imprints of <8>, wherein the polymerizable compound contained in the adhesive composition for imprints has a hydroxy group or carboxyl group.
<10> The method for manufacturing an adhesive film for imprints of any one of <1> to <9>, wherein the base has a rectangular shape.
<11> The method for manufacturing an adhesive film for imprints of any one of <1> to <10>, wherein the base has a surface energy of smaller than 60 mJ/m².
<12> The method for manufacturing an adhesive film for imprints of any one of <1> to <11>, wherein the adhesive composition for imprints is applied in the base by spin coating.
<13> An adhesive film for imprints having a thickness smaller than 1.3 nm.
<14> The adhesive film for imprints of <13>, obtainable by a method for manufacturing an adhesive film for imprints described in any one of <1> to <12>.
<15> The adhesive film for imprints of <13> or <14>, having a surface roughness Ra of 0.6 nm or smaller.
<16> A method for forming a pattern, the method comprising: forming an adhesive film for imprints in a base, by a method for manufacturing an adhesive film for imprints of any one of <1> to <12>; applying a photo-curable composition for imprints on a surface of the adhesive film for imprints; irradiating light on the photo-curable composition for imprints and the adhesive film for imprints, while holding the photo-curable composition for imprints and the adhesive film for imprints between the base and a mold with a fine pattern, to thereby cure the photo-curable composition for imprints; and releasing the mold.
<17> A method for manufacturing a semiconductor device comprising a method for forming a pattern of <16>.
<18> A semiconductor device manufactured by a method for manufacturing a semiconductor device described in <17>.

### Advantageous Effects of Invention

The present invention achieves good profile of etched pattern.

### BRIEF DESCRIPTION OF DRAWINGS

FIG. 1 illustrates an exemplary manufacturing process when the curable composition for imprints is used for working of a substrate by etching.

### DESCRIPTION OF EMBODIMENTS

The contents of the invention are described in detail hereinunder. In this description, the numerical range expressed by the wording “a number to another number” means the range that falls between the former number indicating the lowermost limit of the range and the latter number indicating the uppermost limit thereof.

methacrylate; “(meth)acrylic” means acrylic and methacrylic; “(meth)acryloyl” means acryloyl and methacryloyl. In the invention, monomer is differentiated from oligomer and polymer, and the monomer indicates a compound having a weight-average molecular weight of at most 1,000. In this specification, “functional group” means a group relevant to polymerization reaction.

“Imprint” referred to in the invention is meant to indicate pattern transfer in a size of from 1 nm to 10 mm and preferably meant to indicate pattern transfer in a size of from about 10 nm to 100 (nanoimprint).

Regarding the expression of “group (atomic group)” in this description, the expression with no indication of “substituted” or “unsubstituted” includes both “substituted group” and “unsubstituted group”. For example, “alkyl group” includes not only an alkyl group not having a substituent (unsubstituted alkyl group) but also an alkyl group having a substituent (substituted alkyl group).

### [Method for Manufacturing Adhesive Film for Imprints]

The method for manufacturing an adhesive film for imprints of this invention is characterized in that after an adhesive composition for imprints (may simply be referred to as “adhesive composition”, hereinafter) is applied in a base, the adhesive composition for imprints is rinsed.

### Rinsing

Rinsing in this invention means a treatment for removing an excessive portion of the adhesive composition. By such rinsing, the excessive portion of the adhesive composition may be removed, and thereby the obtainable adhesive film may have a more uniform thickness. Accordingly, when the photo-curable composition for imprints is applied onto the surface of such adhesive film, and the photo-curable composition for imprints is allowed to cure, a resist profile will not adversely be affected, and thereby a good profile of etched pattern may be obtained.

Method of rinsing in this invention is exemplified by dip coating, air knife coating, curtain coating, wire bar coating, gravure coating, extrusion coating, spin coating and slit scanning. Spin coating is preferable from the viewpoint of making the thickness of the adhesive film more uniform.

For the rinsing in this invention, it is preferable to use a composition for rinsing capable of dissolving the adhesive composition, and to apply the composition for rinsing over the adhesive composition.

While the composition for rinsing is not specifically limited so long as it can dissolve therein the adhesive composition, it preferably contains a solvent, and it is more preferable that it substantially contains a solvent only. Now “it substantially contains a solvent only” means that the solvent in the composition for rinsing accounts for 90% by mass or more, more preferably 95% by mass or more, and furthermore preferably 99% by mass or more. The upper limit of the content of solvent in the composition is 100% by mass, although not specifically limited. The composition for rinsing may be added with any of surfactants described later.

As the solvent used for rinsing, it is preferable to use, for example, a solvent having a boiling point at normal pressure of 50 to 180° C., and it is more preferable to use a solvent having a boiling point at normal pressure of 80 to 160° C. By using the solvent having the boiling point in these ranges, the adhesive film after rinsed will dry well and will have a uniform thickness. From the viewpoint of easiness in removing the adhesive composition, the solvent preferably has at least one of ester structure, ketone structure, hydroxy group, and ether structure.

More specifically, the solvent is preferably one of, or mixture of solvents selected from propylene glycol monomethyl ether acetate, cyclohexanone, 2-heptanone, γ-butyrolactone, propylene glycol monomethyl ether, ethyl lactate, MIBC (methyl isobutyl carbinol) and butyl acetate, and particularly propylene glycol monomethyl ether acetate. The solvent used for rinsing is preferably same as the solvent used for the adhesive composition described later. The solvent may be a single species used independently, or two or more species used in combination.

Method of applying the composition for rinsing over the adhesive composition may be a method of placing the composition for rinsing on the adhesive composition by a well-known coating method or dropping method. A method of dropping the composition for rinsing onto the adhesive composition is preferable.

In the rinsing, the amount of application of the composition for rinsing over the adhesive composition is preferably, for example, 10 to 100% of the amount of applied liquid for contact treatment, although not specifically limited. With such configuration, the effect of this invention tends to be exhibited more efficiently.

The rinsing in this invention is preferably effected by spin coating, over the time from the start to the end of rinsing. Now the start of rinsing means a point of time when the above-described composition for rinsing is applied over the adhesive composition, and the operation such as spin coating is started. Meanwhile the end of rinsing means a point of time when the operation such as spin coating is terminated.

In the rinsing in this invention, when implemented by spin coating, and assuming the time range from the start to the end of rinsing as T, it is preferable to set the number of rotation, at which the base is spun, smaller in the time range immediately after the start of rinsing, than in the time range immediately before the end of rinsing.

For example, it is preferable to reduce the number of rotation (rpm), at which the base is spun, in a time range up to 0.005T to 0.3T, preferably up to 0.02T to 0.2T, after the start of rinsing, than in a time range up to 0.6T to 0.95T, preferably up to 0.8T to 0.9T, before the end of rinsing.

In the time range up to 0.005T to 0.3T after the start of rinsing (first step), the base is preferably spun at a low speed (for example, 50 to 150 rpm) for the purpose of dissolving an excessive portion of the adhesive composition into the composition for rinsing. Meanwhile, the the base is preferably spun at a high speed (for example, 4000 to 6000 rpm) in a time range from 0.1T to 0.9T (second step), for the purpose of efficiently removing the composition for rinsing which contains the excessive portion of the adhesive composition. It is further preferable that the base is spun at a higher speed (for example, 1000 to 2000 rpm) in the time range from 0.6T up to 0.95T before the end of rinsing (third step) than in the first step, for the purpose of drying the surface of the base.

For example, in the rinsing in this invention, the base is spun at 50 to 150 rpm in the time range up to 0.5 to 2 seconds after the start of rinsing (throughout the first step); at 4000 to 6000 rpm in the time range up to 3 to 8 seconds after the first step (throughout the second step), and at 1000 to 2000 rpm in the time range up to 20 to 40 seconds after the second step (throughout the third step).

Temperature of rinsing in this invention is typically 10 to 40° C., but not specifically limited. The effect of this invention may be sufficiently achieved, even at normal temperature.

In the rinsing in this invention, the second and subsequent rinsing may be carried out in the same way using different compositions for rinsing if necessary. It is alternatively preferable to use a fluorine-containing solvent, which can rapidly dry after being applied, for the finish rinsing. As the fluorine-containing solvent, for example, solvents having a boiling point at normal pressure of 40 to 70° C. are preferably used. For example, hydrofluoroether (HFE), hydrofluorocarbon (HFC), hydrochlorofluorocarbon (HCFC), perfluorocarbon (PFC) and so forth may be used, among which HFC or HFE is particularly preferable. More specifically, Vertrel XF-UP and Vertrel Supurion from DuPont-Mitsui Fluorochemicals Company, Ltd., and HFE-7100DL from Sumitomo 3M Ltd. are preferable.

The rinsing in this invention is preferably started within one hour after the adhesive composition is applied in the base, more preferably within 40 minutes, furthermore preferably within 30 minutes, and particularly within 10 minutes. By starting the rinsing within one hour after the adhesive composition is applied in the base, for example, the excessive portion of the adhesive composition may be removed before the solvent in the adhesive composition vaporizes off, and thereby the obtainable adhesive film may have a more uniform thickness.

### Adhesive Composition

The adhesive composition used in this invention preferably contains polymerizable compound (A) and solvent (B).

### Polymerizable Compound (A)

The polymerizable compound (A) used in this invention is preferably, for example, a (meth)acrylic resin having ethylenic unsaturated group (P) and hydrophilic group (Q).

The ethylenic unsaturated group (P) is exemplified by (meth)acryloyloxy group, (meth)acryloylamino group, maleimide group, allyl group, and vinyl group.

The hydrophilic group (Q) is exemplified by alcoholic hydroxy group, carboxyl group, phenolic hydroxy group, ether group (preferably polyoxyalkylene group), amino group, amido group, imido group, ureido group, urethane group, cyano group, sulfonamido group, lactone group, and cyclocarbonate group. When the hydrophilic group is urethane group, the urethane group is preferably adjoined by an oxygen atom, and exists in the form of —O—C(═O)—NH— in the resin.

The acrylic resin preferably contains 20 to 100 mol % of a repeating unit which contains the ethylenic unsaturated group (P). The acrylic resin preferably contains 20 to 100 mol % of repeating unit which contains the hydrophilic group (Q).

The ethylenic unsaturated group (P) and the hydrophilic group (Q) may be contained in the same repeating unit, or may be contained in different repeating units.

The acrylic resin may further contain other repeating unit which contain neither the ethylenic unsaturated group (P) nor the hydrophilic group (Q). The content of the other repeating unit in the acrylic resin is preferably 50 mol % or less.

The acrylic resin (A) preferably contains the repeating unit represented by the formula (I) and/or the repeating unit represented by the formula (II) below:

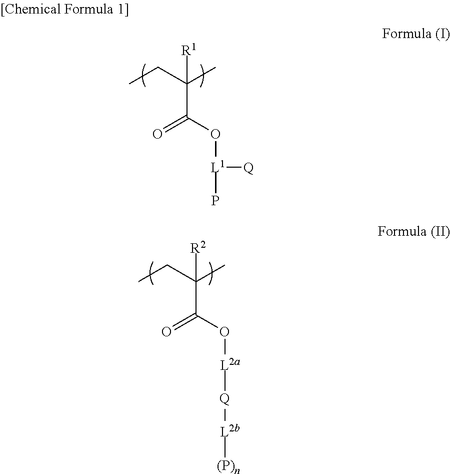

(in the formulae (I) and (II), each of R¹ and R² independently represents a hydrogen atom, methyl group or hydroxymethyl group, L¹ represents a trivalent linking group, L^{2a} represents a single bond or divalent linking group, L^{2b} represents a single bond, divalent linking group or trivalent linking group, P represents an ethylenic unsaturated group, Q represents a hydrophilia hydrophilic group, and n is 1 or 2).

Each of R¹ and R² independently represents a hydrogen atom, methyl group, or hydroxymethyl group, wherein hydrogen atom and methyl group are preferable, and methyl group is more preferable.

L¹ represents a trivalent linking group, which is an aliphatic group, alicyclic group, aromatic group, or trivalent group formed by combining them, and may contain an ester bond, ether bond, sulfide bond or nitrogen atom. The trivalent linking group preferably has 1 to 9 carbon atoms.

L^{2a} represents a single bond or divalent linking group. The divalent linking group is an alkylene group, cycloalkylene group, arylene group, or divalent group formed by combining them, and may contain an ester bond, ether bond or sulfide bond. The divalent linking group preferably has preferably has 1 to 8 carbon atoms.

L^{2b} represents a single bond, divalent linking group, or trivalent linking group. The divalent linking group represented by L^{2b} is synonymous to the divalent linking group represented by L^{2a}, with the same preferable ranges. The trivalent linking group represented by L^{2b} is synonymous to the trivalent linking group represented by L¹, with the same preferable ranges.

P represents an ethylenic unsaturated group, and is synonymous to the ethylenic unsaturated group exemplified above, with the same preferable examples.

Q represents a hydrophilic group, and is synonymous to the hydrophilic group exemplified above, with the same preferable examples.

n is 1 or 2, and preferably 1.

All of L¹, L^{2a} and L^{2b} have neither ethylenic unsaturated group nor hydrophilic group.

The acrylic resin (A) may additionally have the repeating units represented by the formula (III) and/or the formula (IV) below:

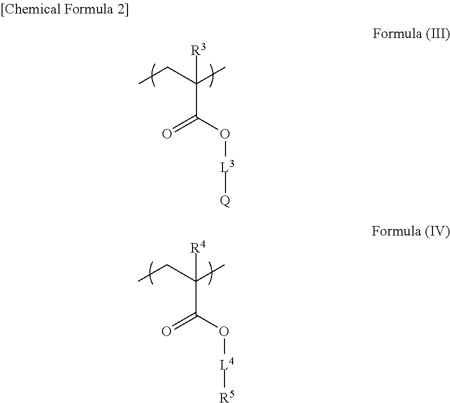

(in the formulae (III) and (IV), each of R³ and R⁴ independently represents a hydrogen atom, methyl group or hydroxymethyl group, each of L³ and L⁴ independently represents a single bond or divalent linking group, Q represents a hydrophilic group, and R⁵ represents a C₁-C₁₂ aliphatic group, C₃₋₁₂ alicyclic group or C₆₋₁₂ aromatic group).

Each of R³ and R⁴ independently represents a hydrogen atom, methyl group or hydroxymethyl group, wherein hydrogen atom and methyl group are preferable, and methyl group is more preferable.

Each of L³ and L⁴ independently represents a single bond or divalent linking group. The divalent linking group is synonymous to the divalent linking group represented by L^{2a} in the formula (I), with the same preferable ranges.

Q represents a hydrophilic group, and is synonymous to the nonionic hydrophilic group exemplified above, with the same preferable examples.

R⁵ represents a C₁₋₁₂ aliphatic group, alicyclic group or aromatic group.

The C₁₋₁₂ aliphatic group is exemplified by C₁₋₁₂ alkyl groups (for example, methyl group, ethyl group, propyl group, isopropyl group, butyl group, isobutyl group, t-butyl group, pentyl group, isopentyl group, neopentyl group, hexyl group, heptyl group, octyl group, 2-ethylhexyl group, 3,3,5-trimethylhexyl group, isooctyl group, nonyl group, isononyl group, decyl group, isodecyl group, undecyl group, and dodecyl group).

The C₃₋₁₂ alicyclic group is exemplified by C₃₋₁₂ cycloalkyl groups (for example, cyclopentyl group, cyclohexyl group, norbornyl group, isobornyl group, adamantyl group and tricyclodecanyl group).

The C₆₋₁₂ aromatic group is exemplified by phenyl group, naphthyl group, and biphenyl group. Among them, phenyl group and naphthyl group are preferable.

The aliphatic group, alicyclic group and aromatic group may have a substituent.

Specific examples of the resin (A) used in the present invention are listed below. In the specific examples below, x stands for 0 to 50 mol %, y stands for 0 to 50 mol %, and z stands for 20 to 100 mol %.

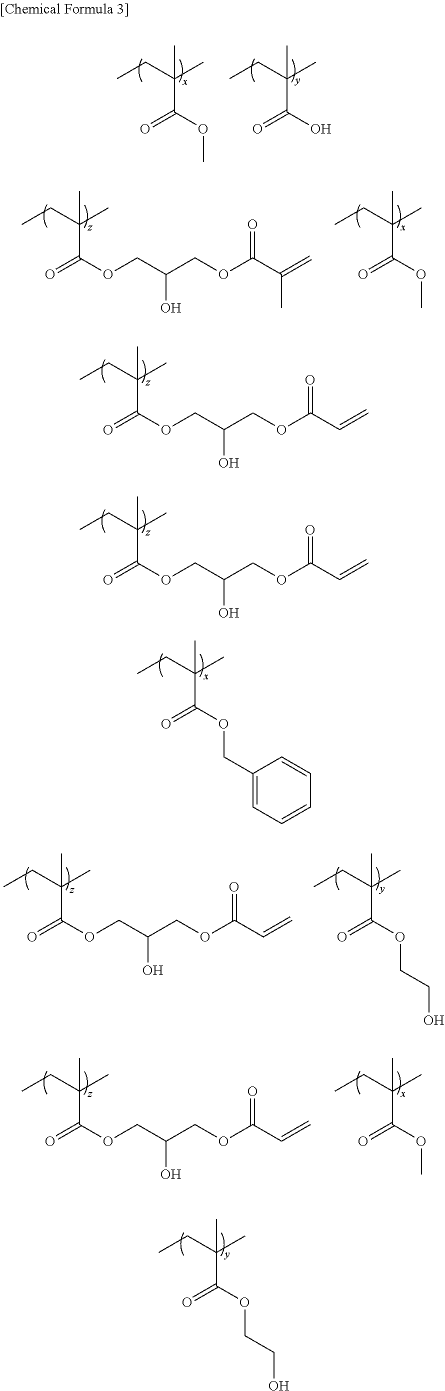

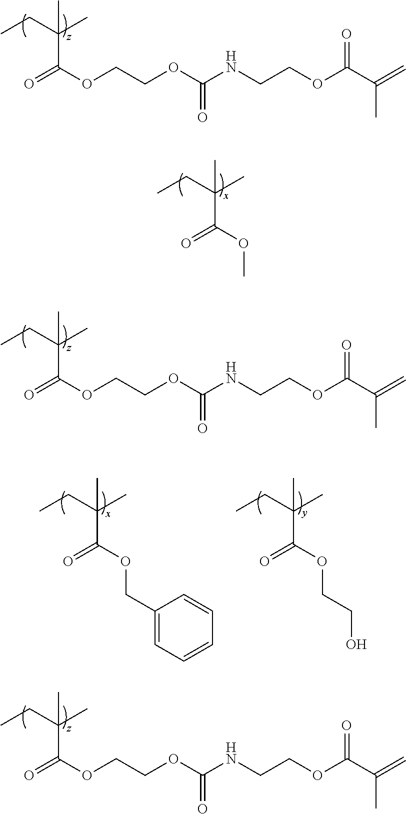

The polymerizable compound (A) usable in this invention may be those having an aromatic ring in the principal chain thereof. Such polymerizable compound (A) is exemplified by those having the principal chain composed of aromatic rings and an alkylene groups, and by those having the principal chain configured by benzene rings and methylene groups which are alternatively bound.

The polymerizable compound (A) used in this invention preferably has a reactive group in the side chain thereof, more preferably has a (meth)acryloyl group in the side chain thereof, and furthermore preferably has a acryloyl group in the side chain thereof.

The polymerizable compound (A) used in this invention may be a polymer mainly composed of a constitutive unit represented by Formula (A) below. The polymer more preferably has a content of the constitutive unit represented by Formula (A) of 90 mol % or more.

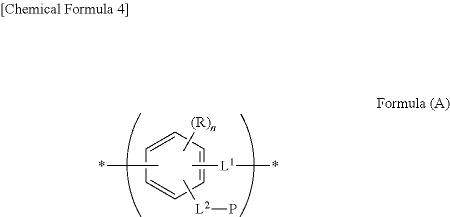

(In Formula (A), R represents an alkyl group, each of L¹ and L² independently represents a divalent linking group, and P represents a polymerizable group. n represents an integer of 0 to 3.)

R preferably represents an alkyl group having 1 to 5 carbon atoms, and more preferably a methyl group.

L¹ preferably represents an alkylene group, which is preferably an alkylene group having 1 to 3 carbon atoms, and more preferably —CH₂—.

L² preferably represents —CH₂—, —O—, —CHR (R represents a substituent)-, and divalent linking group configured by combining two or more of them. R preferably represents an OH group.

P preferably represents a (meth)acryloyl group, and more preferably an acryloyl group.

n preferably represents an integer of 0 to 2, and more preferably an integer of 0 or 1.

The polymerizable compound (A) used in this invention is specifically exemplified by epoxy (meth)acrylate polymer.

The polymerizable compound (A) is further exemplified typically by those described in paragraphs [0040] to [0056] of JP-T-2009-503139, the contents of which are incorporated into this specification.

Among the above-described examples of the polymerizable compound (A), those having a functional group showing high adhesiveness to the base are preferable. Preferable examples of the functional group showing high adhesiveness to the base include hydroxy group, carboxyl group, amino group, and silane coupling group. Hydroxy group and carboxyl group are particularly preferable.

While the polymerizable compound (A) used in this invention may contain a cyclic structure such as aromatic cyclic structure, it preferably contains substantially no cyclic structure. Now “contains substantially no cyclic structure” means that ratio of content of the cyclic structure in the polymerizable compound (A) is 1% by mass or less relative to the whole composition of the polymerizable compound (A). By containing substantially no cyclic structure, the polymerizable compound (A) will not show excessively strong molecular interaction, and will be enough to ensure the effect of rinsing.

The polymerizable compound (A) generally has a molecular weight of 1000 or larger, may be a low molecular weight compound or may be a polymer, and preferably be a polymer. The polymerizable compound (A) more preferably has a molecular weight of 3000 or larger, and furthermore preferably 7500 or larger. The upper limit of the molecular weight of the polymerizable compound (A) is preferably 200000 or smaller, more preferably 100000 or smaller, and furthermore preferably 50000 or smaller. With such molecular weight, the polymerizable compound (A) may be suppressed from vaporizing.

The content of the polymerizable compound (A) in the adhesive composition used in this invention is preferably 30% by mass or more of the whole composition of the adhesive composition excluding the solvent, more preferably 50% by mass or more, and furthermore preferably 70% by mass or more.

### Solvent (B)

The adhesive composition of this invention preferably contains a solvent. While any species of solvent is usable so long as it can dissolve the polymerizable compound (A) described above, the solvent preferably has any one or more of ester structure, ketone structure, hydroxy group, and ether structure. More specifically, the solvent is preferably a single or mixed solvent selected from propylene glycol monomethyl ether acetate, cyclohexanone, 2-heptanone, γ-butyrolactone, propylene glycol monomethyl ether, and ethyl lactate. Propylene glycol monomethyl ether acetate is particularly preferable.

Preferable solvent is such as having a boiling point at normal pressure of 80 to 200° C., and more preferably having a boiling point at normal pressure of 50 to 180° C.

Content of the solvent in the adhesive composition is optimized depending on the viscosity of ingredients excluding solvent, coatability, and target thickness of the film. From the viewpoint of improving the coatability, the amount of addition may be 70% by mass or more of the whole composition, preferably 90% by mass or more, more preferably 95% by mass or more, and furthermore preferably 99% by mass or more. The upper limit of the content of solvent in the adhesive composition is 100% by mass or less, although not specifically limited.

### Other Component

The adhesive composition used in this invention may contain, as the other component, at least one species of crosslinking agent, catalyst, surfactant, heat polymerization initiator, and polymerization inhibitor.

The amount of addition of the other component is preferably 50% by mass or less of the whole composition excluding the solvent. It is particularly preferable that the adhesive composition used in this invention is substantially composed of the polymerizable compound (A) and the solvent only. Now “substantially composed of the polymerizable compound (A) and the solvent only” means that any component other than the polymerizable compound (A) and the solvent is not contained at a level capable of affecting the effect of this invention, and typically means that the other component accounts for 2% by mass or less of the whole composition. The other component preferably accounts for 1% by mass or less of the total component, and more preferably 0% by mass of the total component.

### Method of Preparing Adhesive Composition

The adhesive composition of this invention may be prepared by mixing the individual components described above. After mixing the individual components, the mixture is preferably filtered through a filter having a pore size of 0.003 μm to 5.0 μm. The filtration may be a multi-stage process or may be repeated multiple times. The filtrate may be re-filtered. Filter material used for the filtration is not specifically limited, and is exemplified by polyethylene resin, polypropylene resin, fluorine-containing resin and nylon resin.

### Base

The base (substrate or support), onto which the adhesive composition of this invention is applied, is selectable depending on various applications without special limitation. The base is exemplified by those composed of quartz, glass, optical film, ceramic material, evaporated film, magnetic film, reflective film, metal base (for example, Ni, Cu, Cr, Fe), paper, SOG (Spin On Glass), polymer base (for example, polyester film, polycarbonate film, polyimide film), TFT array base, electrode panel for PDP, glass or translucent plastic base, electro-conductive base, insulating base (for example, ITO and metal), and semiconductor manufacturing base (for example, silicon, silicon nitride, polysilicon, silicon oxide, and amorphous silicon). When intended to be etched just like in this invention, the base is preferably a semiconductor manufacturing base.

Shape of the base is not specifically limited, and may be sheet or roll, and circular or rectangular. The base is selectable from translucent and non-translucent ones, depending on combination with the mold as described later.

It has been known that the rectangular base, such as square substrate or square mesa-containing substrate, shows poor coatability due to its low surface energy (for example, surface energy is smaller than 60 mJ/m²), tends to have excessive adhesive composition on four corners thereof, thereby the thickness distribution of the adhesive film would be large, enough to degrade the resist profile. It has therefore been difficult to form, by coating, an adhesive film of thinner than 1.3 nm on the rectangular base. It has also been anticipated that when the square substrate is brought into contact with the base for imprinting, the base if having thereon the adhesive film thickened at four corners, may result in contact failure at the four corners thereof.

According to the method for manufacturing an adhesive film of this invention, by virtue of the rinsing, even when the square substrate having a surface energy of smaller than 60 mJ/m² is used, the adhesive composition is suppressed from residing excessively at the four corners, so as to prevent the thickness distribution of the adhesive film from increasing. Accordingly, by the method for manufacturing an adhesive film of this invention, the adhesive film may be formed with a thickness of smaller than 1.3 nm, without adversely affecting the resist profile.

### Method of Applying Adhesive Composition

Method of applying the adhesive composition in the base is preferably a method of coating the adhesive composition in the base. The adhesive composition may be coated or placed in the form of droplets, typically by dip coating, air knife coating, curtain coating, wire bar coating, gravure coating, extrusion coating, spin coating, slit scanning, or ink jet process. Among these methods, spin coating is preferable from the viewpoint of making the thickness of the adhesive film uniform.

While the amount of application of the adhesive composition in the base is not specifically limited, the amount is preferably determined, for example, so that the resultant adhesive film will have a thickness of smaller than 1.3 nm. While the lower limit of the amount of application of the adhesive composition in the base is again not specifically limited, the amount is preferably determined, for example, so that the resultant adhesive film will have a thickness of 0.1 nm or larger.

The number of times the adhesive composition is applied in the base may be once, twice or more.

### Baking

In the method for manufacturing an adhesive film of this invention is followed by baking (drying). The baking is a treatment for drying off the solvent which remain in the adhesive composition after the rinsing. Temperature of the baking is preferably 70 to 130° C. In the baking, it is preferable to further cure the rinsed adhesive composition by an active energy (preferably heat and/or light), and in particular, it is preferable to proceed curing under heating at 150 to 300° C. for 30 to 90 seconds. A step of drying off the solvent which resides in the adhesive composition and a step of curing the adhesive composition may proceed concurrently.

### [Adhesive Film]

While the thickness of the adhesive film, obtainable by the method for manufacturing an adhesive film of this invention, may vary depending on intended applications, it is preferably smaller than 1.3 nm, more preferably 0.7 nm or smaller, furthermore preferably 0.6 nm or smaller, and particularly 0.5 nm or smaller. The lower limit of the thickness of the adhesive film is typically 0.1 nm or above, although not specifically limited.

The adhesive film in this invention preferably has a surface roughness Ra of 0.6 nm or smaller, and more preferably 0.5 nm or smaller. With such surface roughness, the adhesive film will have a more uniform thickness, so that the resist profile will not adversely be affected, and thereby a good profile of etched pattern may be obtained. For example, by carrying out the rinsing of this invention, the surface roughness Ra of the adhesive film of this invention may be reduced to 0.6 nm or smaller. The surface roughness Ra of the adhesive film may be measured by using, for example, an AFM (atomic force microscope).

### Process

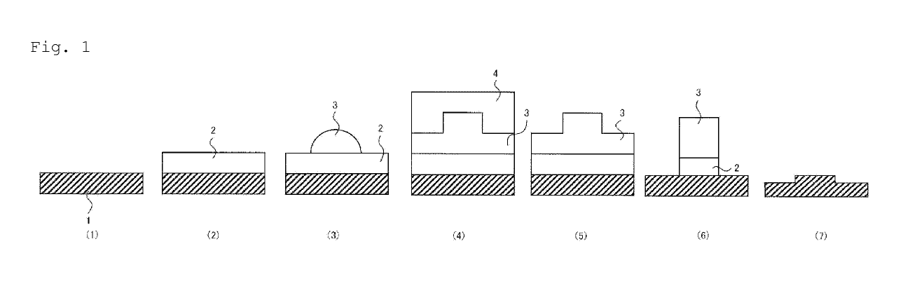

FIG. 1 is a schematic drawing illustrating an exemplary process of manufacturing in which the base is etched using the photo-curable composition for imprints. As seen in FIG. 1, a curable composition 2 is applied over the surface of a base 1 (2), a photo-curable composition for imprints 3 is applied on the surface of the adhesive composition 2 (3), and a mold 4 is placed on the surface of the photo-curable composition for imprints 3 (4). After irradiating light onto the photo-curable composition for imprints 3, the mold 4 is released from the surface of the photo-curable composition for imprints 3 (5). Etching is proceeded according to a pattern formed by the photo-curable composition for imprints 3 (6), and the photo-curable composition for imprints 3 and the adhesive composition 2 are removed, to thereby form the base having a desired pattern formed thereon (7). Now, the adhesiveness between the base 1 and the photo-curable composition for imprints 3 is critical, since the pattern of the mold 4 cannot be imprinted correctly if the adhesiveness between the base 1 and the photo-curable composition for imprints 3 is poor.

### [Method for Forming Pattern]

A method for forming a pattern (pattern imprinting method) of this invention, using the photo-curable composition for imprints, will be detailed below.

The method for forming a pattern of this invention includes a step of forming the adhesive film in a base, by the method for manufacturing an adhesive film described above; a step of applying a photo-curable composition for imprints on the surface of the adhesive film; a step of irradiating light on the photo-curable composition and the adhesive film, while holding them between the base and a mold with a fine pattern, to thereby cure the photo-curable composition for imprints; and a step of releasing the mold. The step of forming the adhesive film in the base has been described previously, so that it will not be detailed again.

In the step of applying the photo-curable composition for imprints on the surface of the adhesive film, a pattern-forming layer is formed by applying the photo-curable composition for imprints on the surface of the adhesive film.

First, the photo-curable composition for imprints will be explained in the next.

### Photo-Curable Composition for Imprints

The photo-curable composition for imprints in this invention generally contains a polymerizable compound (C) and a polymerization initiator (D).

### Polymerizable Compound (C)

While the polymerizable compound (C) used in the photo-curable composition for imprints, employed in this invention, is not specifically limited without departing from the spirit of this invention, it is exemplified by polymerizable unsaturated monomer having 1 to 6 ethylenic unsaturated bond-containing groups; epoxy compound, oxetane compound; vinyl ether compound; styrene derivative; propenyl ether and butenyl ether. The photo-curable composition for imprints (C) preferably has a polymerizable group capable of polymerizing with a polymerizable group possessed by the adhesive composition.

The polymerizable unsaturated monomer having 1 to 6 ethylenic unsaturated bond-containing group (monovalent to hexavalent polymerizable unsaturated monomer) will be explained.

The polymerizable unsaturated monomer having one ethylenic unsaturated bond-containing group is exemplified by those typically described in paragraph [0026] of JP-A-2012-175017, the contents of which are incorporated into this specification.

Among the monofunctional polymerizable compounds having the ethylenic unsaturated bond, it is preferable in this invention to use monofunctional (meth)acrylate compound, from the viewpoint of photo-curability. The monofunctional (meth)acrylate compound is exemplified by the monofunctional (meth)acrylate compounds which have been exemplified as the monofunctional polymerizable compounds having the ethylenic unsaturated bond.

In this invention, it is also preferable to use, as the polymerizable compound, a polyfunctional polymerizable unsaturated monomer which has two or more ethylenic unsaturated bond-containing groups.

Examples of bifunctional polymerizable unsaturated monomer having two ethylenic unsaturated bond-containing groups, preferably used in this invention, are exemplified by those typically described in paragraph [0029] of JP-A-2012-175017, the contents of which are incorporated into this specification.

Among them, it is particularly preferable to use in this invention bifunctional (meth)acrylate such as neopentyl glycol di(meth)acrylate, 1,9-nonanediol di(meth)acrylate, tripropylene glycol di(meth)acrylate, tetraethylene glycol di(meth)acrylate, neopentyl glycol hydroxypivalate di(meth)acrylate, polyethylene glycol di(meth)acrylate, o-, m-, p-benzene di(meth)acrylate, and o-, m-, p-xylylene di(meth)acrylate.

Examples of polyfunctional polymerizable unsaturated monomer having three or more ethylenic unsaturated bond-containing groups are exemplified by those typically described in paragraph [0031] of JP-A-2012-175017, the contents of which are incorporated into this specification.

Among them, trifunctional or higher functional (meth)acrylate, such as EO-modified glycerol tri(meth)acrylate, PO-modified glycerol tri(meth)acrylate, trimethylolpropane tri(meth)acrylate, EO-modified trimethylolpropane tri(meth)acrylate, PO-modified trimethylolpropane tri(meth)acrylate, dipentaerythritol hexa(meth)acrylate, pentaerythritol ethoxy tetra(meth)acrylate, and pentaerythritol tetra(meth)acrylate are preferably used for this invention.

Among the polyfunctional polymerizable unsaturated monomer having two or more ethylenic unsaturated bonds, polyfunctional (meth)acrylate is preferably used in this invention, from the viewpoint of photo-curability. The polyfunctional (meth)acrylate in this context generally means bifunctional (meth)acrylate and three- or hither-functional (meth)acrylate. The polyfunctional (meth)acrylate is specifically exemplified by various polyfunctional (meth)acrylates which have been exemplified as the polyfunctional polymerizable unsaturated monomer having two ethylenic unsaturated bonds, and have been exemplified as the polyfunctional polymerizable unsaturated monomer having three or more ethylenic unsaturated bonds.

The compound having an oxirane ring (epoxy compound) is exemplified by those typically described in paragraph [0034] of JP-A-2012-175017, the contents of which are incorporated into this specification. Only a single species of these compounds may be used independently, or two or more species thereof may be used in a mixed manner.

The compound having an oxirane ring (epoxy compound) preferably used in this invention is exemplified by those typically described in paragraph [0053] of JP-A-2009-73078, the contents of which are incorporated into this specification.

Among them, bisphenol-A diglycidyl ether, bisphenol-F diglycidyl ether, hydrogenated bisphenol-A diglycidyl ether, hydrogenated bisphenol-F diglycidyl ether, 1,4-butanediol diglycidyl ether, 1,6-hexanediol diglycidyl ether, glycerin triglycidyl ether, trimethylolpropane triglycidyl ether, neopentyl glycol diglycidyl ether, polyethylene glycol diglycidyl ether, and polypropylene glycol diglycidyl ether are particularly preferable.

Commercially available products of the glycidyl group-containing compound preferably used in this invention are exemplified by those typically described in paragraph [0055] of JP-A-2009-73078, the contents of which are incorporated into this specification. Only a single species of these compounds may be used independently, or two or more species thereof may be used in combination.

These oxirane ring-containing compounds may be manufactured by any arbitrary method, and may be synthesized referring to literatures such as “Dai 4-Han Jikken Kagaku Koza 20 Yuki Gosei II (in Japanese) (4th Edition, The Course of Experimental Chemistry 20, Organic Synthesis II), 213-, 1992, Maruzen Publishing Co., Ltd.; The Chemistry of Heterocyclic Compounds—Small Ring Heterocycles Part 3, Oxiranes, Ed. by Alfred Hasfner, John & Wiley and Sons, An Interscience Publication, New York, 1985; Yoshimura, Adhesion, Vol. 29(12), 32, 1985; Yoshimura, Adhesion, Vol. 30(5), 42, 1986; Yoshimura, Adhesion, Vol. 30(7), 42, 1986; JP-A-H11-100378, Japanese Patent No. 2906245, and Japanese Patent No. 2926262.

Also vinyl ether compound is preferably used, as the polymerizable compound (C) usable in this invention. The vinyl ether compound is arbitrarily selectable from known compounds, and is exemplified by those typically described in paragraph [0039] of JP-A-2012-175017, the contents of which are incorporated into this specification.

These vinyl ether compounds may be synthesized, for example, by a method described by Stephen. C. Lapin in Polymers Paint Colour Journal., 179(4237), 321(1988), that is, by a reaction of polyhydric alcohol or polyhydric phenol with acetylene, or, a reaction of polyhydric alcohol or polyhydric phenol with halogenated alkyl vinyl ether. Only a single species of these compounds may be used independently, or two or more species thereof may be used in a mixed manner.

Also styrene derivative is preferably used, as the polymerizable compound (C) usable in this invention. The styrene compound is exemplified by those typically described in paragraph [0041] of JP-A-2012-175017, the contents of which are incorporated into this specification.

As the polymerizable compound (C) usable in this invention, polymerizable compound having an alicyclic hydrocarbon structure or aromatic group is preferable. By using the polymerizable compound having an alicyclic hydrocarbon structure or aromatic group, a good line edge roughness may be obtained when the photo-curable composition for imprints is used as an etching resist for processing the base. In particular, polyfunctional polymerizable monomer having an alicyclic hydrocarbon structure or aromatic group will show a distinctive effect.

The polymerizable compound (C) having an alicyclic hydrocarbon structure is exemplified by those typically described in paragraph [0095] of JP-A-2012-175017, the contents of which are incorporated into this specification. Also polyfunctional (meth)acrylates having an alicyclic hydrocarbon structure, such as tricyclodecane dimethanol di(meth)acrylate, and 1,3-adamantanediol di(meth)acrylate are preferable.

The polymerizable monomer having an aromatic group, usable in this invention, is preferably a monofunctional (meth)acrylate compound represented by Formula (V) below, or a polyfunctional (meth)acrylate compound represented by Formula (VI) below:

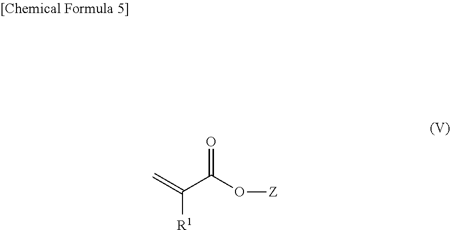

(in Formula (V), Z represents a group having an aromatic group, and R¹ represents a hydrogen atom, alkyl group or halogen atom.)

The monofunctional (meth)acrylate compound represented by Formula (V) is typically referred to the description of paragraphs [0061] to [0062] of JP-A-2012-175017, the contents of which are incorporated into this specification.

The amount of addition of the polymerizable monomer represented by Formula (V) in the photo-curable composition for imprints is preferably 10 to 100% by mass, more preferably 20 to 100% by mass, and particularly 30 to 80% by mass.

Among the compounds represented by formula (V), those having no substituent on the aromatic ring are specifically and preferably exemplified by benzyl (meth)acrylate, phenetyl (meth)acrylate, phenoxyethyl (meth)acrylate, 1- or 2-naphthyl (meth)acrylate, 1- or 2-naphthylmethyl (meth)acrylate, 1- or 2-naphthylethyl (meth)acrylate, and 1- or 2-naphthoxyethyl (meth)acrylate.

As the compound represented by Formula (V), also a compound having a substituent on the aromatic ring, represented by Formula (V-1) below, is preferable:

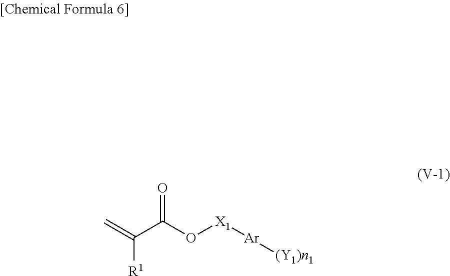

(in Formula (V-1), R¹ represents a hydrogen atom, alkyl group or halogen atom, X¹ represents a single bond or hydrocarbon group, the hydrocarbon group may contain in the chain thereof a heteroatom-containing linking group. Y¹ represents a substituent having a formula weight of 15 or larger, and n1 represents an integer of 1 to 3. Ar represents an aromatic linking group, and is preferably a phenylene group or naphthylene group.)

R¹ is synonymous to R¹ in the foregoing Formula, specified by the same preferable ranges.

X¹ is synonymous to the foregoing Z′, specified by the same preferable ranges.

Y¹ represents a substituent having a formula weight of 15 or larger, and is exemplified by alkyl group, alkoxy group, aryloxy group, aralkyl group, acyl group, alkoxycarbonyl group, alkylthio group, arylthio group, halogen atom, and cyano group. These substituents may further be substituted.

When n1 is 2, X¹ preferably represents a single bond or a hydrocarbon group having a single carbon atom.

In a particularly preferable embodiment, n1 is 1, and X¹ represents an alkylene group having 1 to 3 carbon atoms.

The compound represented by Formula (V-1) is more preferably a compound represented by either Formula (V-2) or Formula (V-3) below. Compound Represented by Formula (V-2)

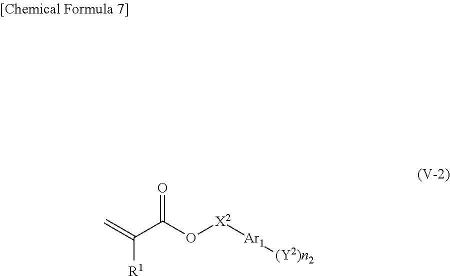

In Formula (V-2), R¹ represents a hydrogen atom, alkyl group or halogen atom. X² represents a single bond or hydrocarbon group, wherein the hydrocarbon group may contain in the chain thereof a heteroatom-containing linking group. Ar1 represents an aromatic linking group, and is preferably a phenylene group or naphthylene group. Y² represents a substituent having a formula weight of 15 or larger, having no aromatic group, and n2 represents an integer of 1 to 3.

R¹ is synonymous to R¹ in the foregoing Formula, specified by the same preferable ranges.

X², if being a hydrocarbon group, is preferably a hydrocarbon group having 1 to 3 carbon atoms, preferably a substituted or unsubstituted alkylene group having 1 to 3 carbon atoms, more preferably a unsubstituted alkylene group having 1 to 3 carbon atoms, and furthermore preferably a methylene group or ethylene group. By employing such hydrocarbon group, the photo-curable composition for imprints will advantageously have a smaller viscosity and a lower volatility.

Y² represents a substituent having a formula weight of 15 or larger and having no aromatic group. The upper limit of the formula weight of Y² is preferably 150 or smaller. Preferable examples of Y² include alkyl groups having 1 to 6 carbon atoms such as methyl group, ethyl group, isopropyl group, tert-butyl group, and cyclohexyl group; halogen atoms in the form of fluoro group, chloro group, and bromo group; alkoxy groups having 1 to 6 carbon atoms such as methoxy group, ethoxy group, and cyclohexyl oxy group; and cyano group.

n2 preferably represents an integer of 1 to 2. When n2 is 1, the substituent Y preferably bounds to the para position. From the viewpoint of viscosity, when n2 is 2, X² preferably represents a single bond or a hydrocarbon group having a single carbon atom.

From the viewpoint of suitably balancing low viscosity and low volatility, the (meth)acrylate compound represented by Formula (V-2) preferably has a molecular weight of 175 to 250, and more preferably 185 to 245.

The (meth)acrylate compound represented by Formula (V-2) also preferably has a viscosity at 25° C. of 50 mPa·s or smaller, and more preferably 20 mPa·s or smaller.

The compound represented by Formula (V-2) is also preferably used as a reaction diluent.

The amount of addition of the compound represented by formula (V-2) in the photo-curable composition for imprints is preferably 10% by mass or more from the viewpoints of the viscosity of the composition and accuracy of the cured pattern, more preferably 15% by mass or more, and particularly 20% by mass or more. Meanwhile, from the viewpoints of tackiness after cured and mechanical strength, the amount of addition is preferably 95% by mass or less, more preferably 90% by mass or less, and particularly 85% by mass or less.

The compounds represented by Formula (V-2) will be enumerated below, by which this invention is, of course, by no means limited. R¹ represents a hydrogen atom, alkyl group or halogen atom.

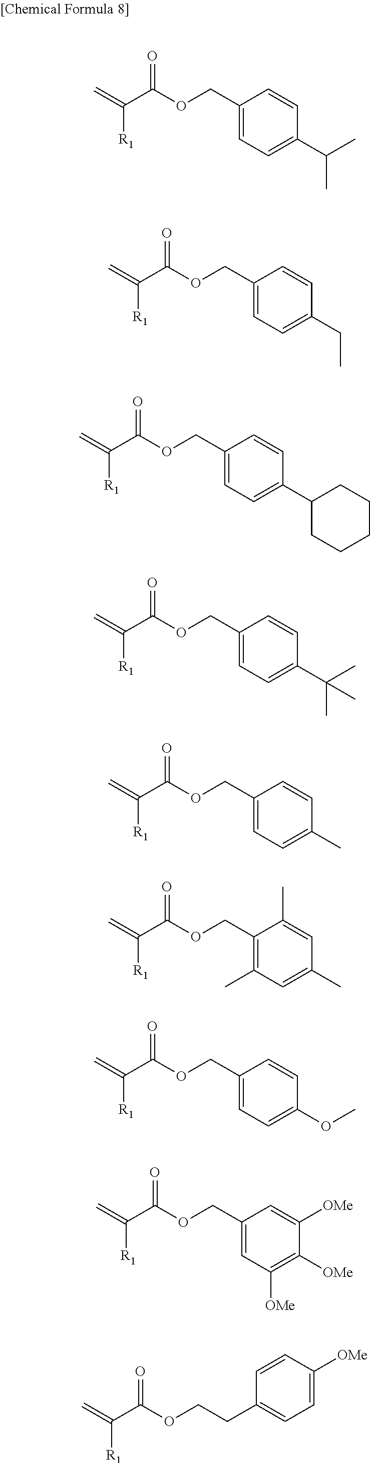

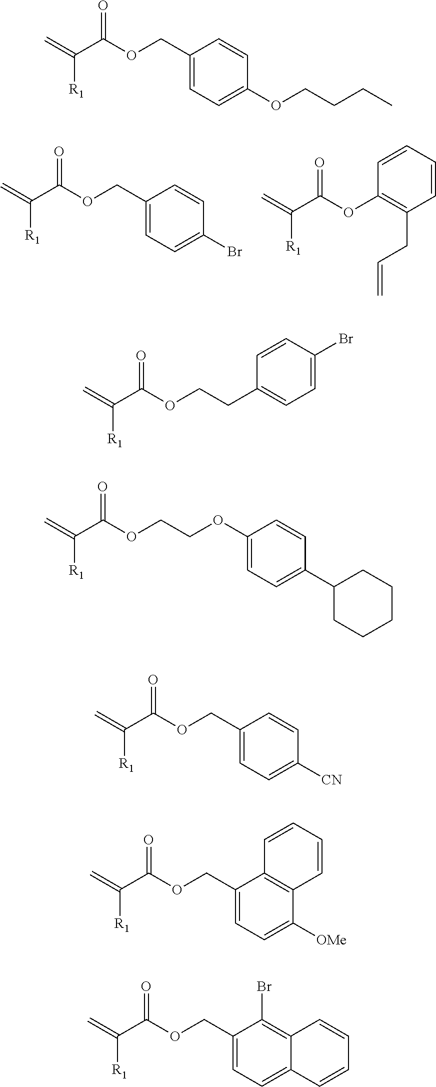

### Compound Represented by Formula (V-3)

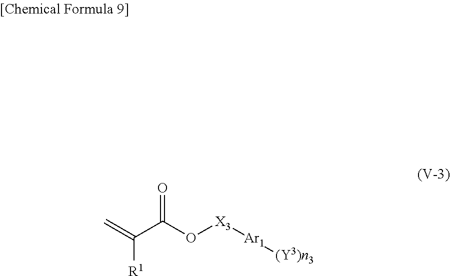

(In formula (V-3), R¹ represents a hydrogen atom, alkyl group or halogen atom, X³ represents a single bond or hydrocarbon group, and the hydrocarbon group may contain, in the chain thereof, a heteroatom-containing linking group. An represents an aromatic linking group, and is preferably a phenylene group or naphthylene group. Y³ represents a substituent having an aromatic group, and n3 represents an integer of 1 to 3.)

R¹ is synonymous to R¹ in the foregoing Formula, specified by the same preferable ranges.

Y³ represents a substituent having an aromatic group. The substituent having an aromatic group is preferably embodied to have the aromatic group bound through a single bond or a linking group to an aromatic ring. The linking group is preferably exemplified by alkylene group, heteroatom-containing linking group (preferably —O—, —S—, —C(═O)O—), and combination of them. Alkylene group, —O—, and groups combining them are more preferable. The substituent having an aromatic group is preferably a substituent having a phenyl group. The substituent having an aromatic group is preferably embodied to have the phenyl group bound through a single bond or the linking group. Phenyl group, benzyl group, phenoxy group, benzyl oxy group, and phenyl thio group are particularly preferable. Y³ preferably has a formula weight of 230 to 350.

n3 is preferably 1 or 2, and more preferably 1.

The amount of addition of the compound represented by Formula (V-3), in the photo-curable composition for imprints used in this invention, is preferably 10% by mass or more, more preferably 20% by mass or more, and particularly 30% by mass or more. Meanwhile, from the viewpoints of tackiness after cured and mechanical strength, the amount of addition is preferably 90% by mass or less, more preferably 80% by mass or less, and particularly 70% by mass or less.

The monofunctional (meth)acrylate compound represented by Formula (V-3) is exemplified by those typically described in paragraph [0074] of JP-A-2012-175017, the contents of which are incorporated into this specification.

### Polyfunctional (Meth)Acrylate Compound Represented by Formula (VI)

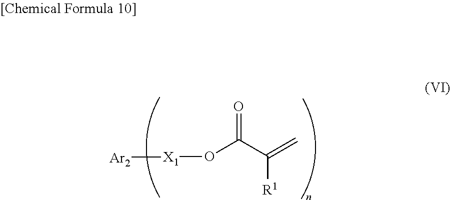

(In Formula (VI), Ar₂ represents an n-valent linking group having an aromatic group, and preferably a linking group having a phenylene group. X₁ and R¹ are synonymous to those described above. n represents 1 to 3, and preferably 1.)

The compound represented by Formula (VI) is preferably a compound represented by Formula (VI-1) or Formula (VI-2) below.

### Compound Represented by Formula (VI-1)

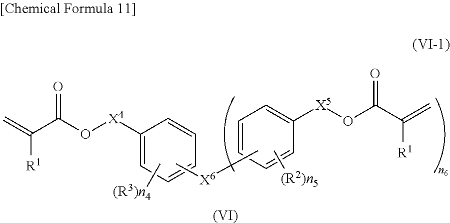

(In Formula (VI-1), X⁶ represents a (n6+1)-valent linking group, each R¹ represents a hydrogen atom, alkyl group, or halogen atom. Each of R² and R³ independently represents a substituent, and each of n4 and n5 represents an integer of 0 to 4. n6 represents 1 or 2, each of X⁴ and X⁵ independently represents a hydrocarbon group, and the hydrocarbon group may contain, in the chain thereof, a heteroatom-containing linking group.)

X⁶ represents a single bond or (n6+1)-valent linking group, and preferably represents an alkylene group, —O—, —S—, —C(═O)O—, and linking group formed by combining a plurality of them. The alkylene group preferably has 1 to 8 carbon atoms, and more preferably has 1 to 3 carbon atoms. Unsubstituted alkylene group is preferable.

n6 preferably represents 1. When n6 represents 2, each set of the plurality of (R¹)s, (X⁵)s and (R²)s may be same or different.

Each of X⁴ and X⁵ independently and preferably represents an alkylene group having no linking group, more preferably an alkylene group having 1 to 5 carbon atoms, furthermore preferably an alkylene group having 1 to 3 carbon atoms, and most preferably a methylene group.

R¹ is synonymous to R¹ in the foregoing Formula, specified by the same preferable ranges.

Each of R² and R³ independently represents a substituent which is preferably an alkyl group, halogen atom, alkoxy group, acyl group, acyloxy group, alkoxycarbonyl group, cyano group, or nitro group. The alkyl group preferably has 1 to 8 carbon atoms. The halogen atom is exemplified by fluorine atom, chlorine atom, bromine atom and iodine atom, and is preferably fluorine atom. The alkoxy group preferably has 1 to 8 carbon atoms. The acyl group preferably has 1 to 8 carbon atoms. The acyloxy group preferably has 1 to 8 carbon atoms. The alkoxycarbonyl group preferably has 1 to 8 carbon atoms.

Each of n4 and n5 independently represents an integer of 0 to 4. When n4 or n5 represents 2, each set of the plurality of (R²)s and (R³)s may be same or different.

The compound represented by Formula (VI-1) is preferably a compound represented by Formula (VI-1a) below.

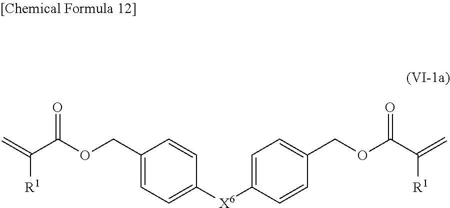

(In Formula (VI-1a), X⁶ represents an alkylene group, —O—, —S—, and linking formed by combining a plurality of them. Each R¹ independently represents a hydrogen atom, alkyl group, or halogen atom.)

R¹ is synonymous to R¹ in the foregoing Formula, specified by the same preferable ranges.

When X⁶ represents an alkylene group, the alkylene group preferably has 1 to 8 carbon atoms, and more preferably has 1 to 3 carbon atoms. Unsubstituted alkylene group is preferable.

X⁶ preferably represents —CH₂—, —CH₂CH₂—, —O—, or —S—.

While the content of the compound represented by Formula (VI-1) in the photo-curable composition for imprints used in this invention is not specifically limited, it is preferably 1 to 100% by mass of the total polymerizable monomers from the viewpoint of viscosity of the photo-curable composition, more preferably 5 to 70% by mass, and particularly 10 to 50% by mass.

The compound represented by Formula (V-1) will be enumerated below, by which this invention is, of course, by no means limited. Each R¹ in the formulae below is synonymous to R¹ in Formula (VI-1), specified by the same preferable ranges, and particularly represents a hydrogen atom.

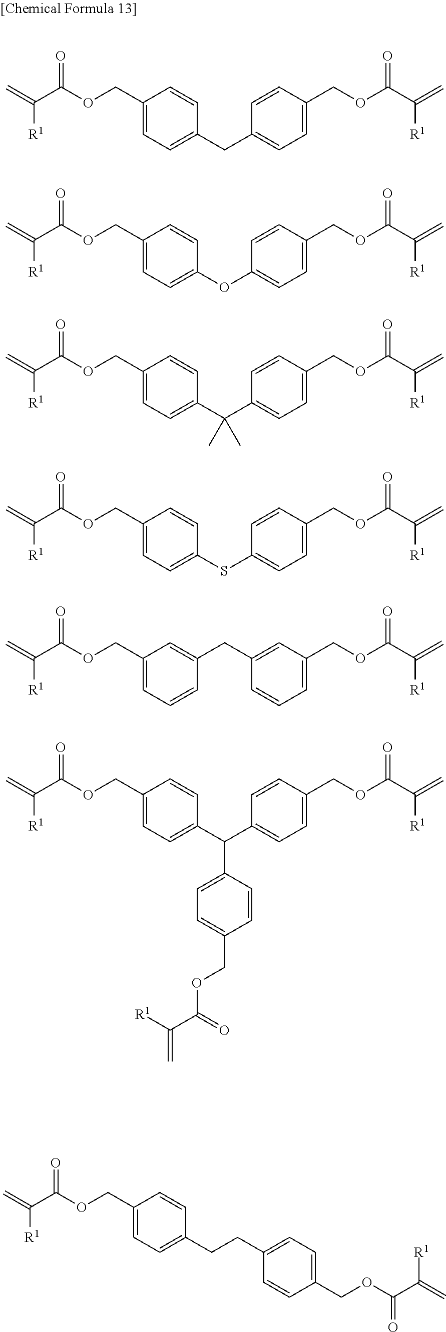

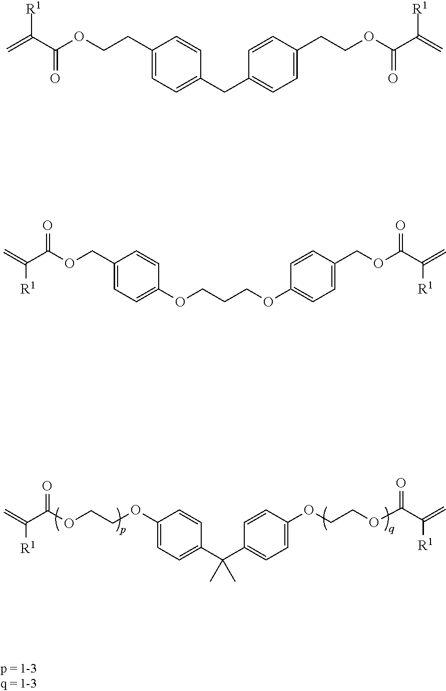

### Polymerizable Monomer Represented by Formula (VI-2)

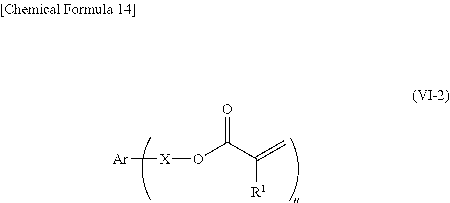

(In Formula (VI-2), Ar represents an optionally-substituted arylene group, X represents a single bond or organic linking group, R¹ represents a hydrogen atom or methyl group, and n represents an integer of 2 or 3.)

The polymerizable monomer represented by Formula (VI-2) is exemplified by those typically described in paragraphs [0083] to [0092] of JP-A-2012-175017, the contents of which are incorporated into this specification.

More preferable and specific examples of the polymerizable compound having an aromatic group used in the photo-curable composition for imprints, employed in this invention, will be enumerated below, by which this invention is by no means limited.

Preferable examples of the polymerizable compound having an aromatic group include benzyl (meth)acrylate which is unsubstituted or substituted on the aromatic ring, phenetyl (meth)acrylate which is unsubstituted or substituted on the aromatic ring, phenoxyethyl (meth)acrylate which is unsubstituted or substituted on the aromatic ring, 1- or 2-naphthyl (meth)acrylate which is unsubstituted or substituted on the aromatic ring, 1- or 2-naphthylmethyl (meth)acrylate which is unsubstituted or substituted on the aromatic ring, 1- or 2-naphthylethyl (meth)acrylate which is unsubstituted or substituted on the aromatic ring, 1- or 2-naphthoxyethyl (meth)acrylate, resolcinol di(meth)acrylate, m-xylylene di(meth)acrylate, naphthalene di(meth)acrylate, and ethoxylated bisphenol-A diacrylate. Diacrylate is preferable, and benzyl acrylate which is unsubstituted or substituted on the aromatic ring, 1- or 2-naphthylmethyl acrylate, and m-xylylene diacryalte are more preferable.

For the purpose of improving the releasability from the mold, the photo-curable composition for imprints preferably contains a polymerizable compound having at least either fluorine atom or silicon atom.

The polymerizable compound having at least either fluorine atom or silicon atom in this invention is a compound having at least one group which contains fluorine atom, or fluorine atom, or both of fluorine atom and silicon atom, and at least one polymerizable functional group. The polymerizable functional group is preferably a methacryloyl group, epoxy group, or vinyl ether group.

The polymerizable compound having at least either fluorine atom or silicon atom may be a low molecular weight compound or may be a polymer.

The polymerizable compound having at least either fluorine atom or silicon atom, when being a polymer, may have the repeating unit having at least fluorine atom or silicon atom, and, as a co-polymerizable component, a repeating unit having a polymerizable group in the side chain thereof. Alternatively, the repeating unit having at least either fluorine atom or silicon atom may have a polymerizable group in the side chain thereof, in particular at the terminal. Now the repeating unit having at least either fluorine atom or silicon atom may have an arbitrary skeleton without departing from the spirit of this invention, and may preferably have, for example, a skeleton derived from an ethylenic unsaturated bond-containing group, and more preferably have a (meth)acrylate skeleton. Alternatively, the repeating unit having silicon atom may be such that silicon atom per se configures a repeating unit, just like siloxane structure (for example, dimethylsiloxane structure). The weight-average molecular weight is preferably 2000 to 100000, more preferably 3000 to 70000, and particularly 5000 to 40000.

While the content of the polymerizable compound having at least either fluorine atom or silicon atom in the photo-curable composition for imprints, employed in this invention, is not specifically limited, it is preferably 0.1 to 20% by mass of the total polymerizable compounds, from the viewpoints of improving curability, and reducing viscosity of the composition, more preferably 0.2 to 15% by mass, furthermore preferably 0.5 to 10% by mass, and particularly 0.5 to 5% by mass.

### Fluorine Atom-Containing Polymerizable Compound

The fluorine atom-containing group possessed by the fluorine atom-containing polymerizable compound is preferably selected from fluoroalkyl group and fluoroalkyl ether group.

The fluoroalkyl group is preferably a fluoroalkyl group having 2 to 20 carbon atoms, and more preferably a fluoroalkyl group having 4 to 8 carbon atoms. Preferable fluoroalkyl group is exemplified by trifluoromethyl group, pentafluoroethyl group, heptafluoropropyl group, hexafluoroisopropyl group, nonafluorobutyl group, tridecafluorohexyl group, and heptadecafluorooctyl group.

In this invention, the fluorine atom-containing polymerizable compound preferably has a trifluoromethyl group structure. With the trifluoromethyl group structure, the effect of this invention may be exhibited only with a small amount of addition (for example, 10% by mass or less), so that compatibility with other components may improve, line edge roughness after dry etching may improve, and formability of a repeated pattern may improve.

The fluoroalkyl ether group preferably has a trifluoromethyl group, just like the case of the fluoroalkyl group, and those having perfluoroethyleneoxy group, or perfluoropropyleneoxy group are preferable. Fluoroalkyl ether unit having a trifluoromethyl group such as —(CF(CF₃)CF₂O)—, and/or, unit having a trifluoromethyl group at the terminal of the fluoroalkyl ether group are preferable.

The total number of fluorine atoms possessed by the polymerizable compound having at least either fluorine atom or silicon atom, per molecule, is preferably 6 to 60, more preferably 9 to 40, furthermore preferably 12 to 40, and particularly 12 to 20.

The polymerizable compound having at least either fluorine atom or silicon atom has a fluorine content of 20 to 60%, when defined by the equation below. The polymerizable compound having at least either fluorine atom or silicon atom, when being a polymerizable compound, preferably has a fluorine content of 20 to 60%, and more preferably 35 to 60%. Meanwhile, the polymerizable compound having at least either fluorine atom or silicon atom, when being a polymer having a polymerizable group, more preferably has a fluorine content of 20 to 50%, and furthermore preferably 20 to 40%. By controlling the fluorine content within the suitable ranges, the photo-curable composition for imprints will have an improved compatibility with other components, will reduce pollution on the mold, will improve the line edge roughness after etching, and will improve repetitive patternability. In this specification, the fluorine content is given by the equation below.

Fluorine content={(Number of fluorine atoms in polymerizable compound)×(Atomic weight of fluorine atom)/Molecular weight of polymerizable compound}×100 [Chemical Formula 15]

The fluorine atom-containing group in the polymerizable compound having at least either fluorine atom or silicon atom preferably has a partial structure represented by Formula (VII) below. By employing the compound having such partial structure, the photo-curable composition for imprints will keep a good patternability after repetitive pattern imprinting, and will improve temporal stability of the composition.

Formula (VII)

—CH₂CH₂—CₙF₂ₙ₊₁ [Chemical Formula 16]

(In formula (VII), n represents an integer of 1 to 8, and preferably an integer of 4 to 6.)

Other preferable example of the (A2) polymerizable compound having at least either fluorine atom or silicon atom is exemplified by a compound having a partial structure represented by Formula (VIII) below. The polymerizable compound may, of course, have both of the partial structure represented by Formula (VII) and the partial structure represented by Formula (VIII).

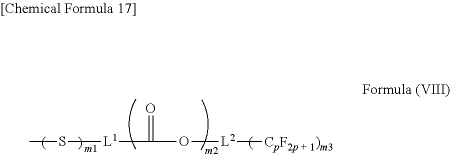

(In formula (VIII), L¹ represents a single bond or alkylene group having 1 to 8 carbon atoms, L² represents an alkylene group having 1 to 8 carbon atoms, each of m1 and m2 independently represents 0 or 1, and at least one of m1 and m2 is 1. m3 represents an integer of 1 to 3, and p represents an integer of 1 to 8. When m3 is 2 or larger, the individual (—CₚF₂ₚ₊₁)s may be same or different.)

It is preferable that each of L¹ and L² independently represents an alkylene group having 1 to 4 carbon atoms. The alkylene group may have a substituent, without departing from the spirit of this invention. m3 preferably represents 1 or 2. p preferably represents an integer of 4 to 6.

Specific examples of the fluorine atom-containing polymerizable compound used for the photo-curable composition for imprints, employed in this invention, will be enumerated below, by which this invention is by no means limited.

The fluorine atom-containing polymerizable compound is exemplified by those typically described in paragraphs [0040] to [0042] of JP-A-2012-072269, the contents of which are incorporated into this specification.

### Silicon Atom-Containing Polymerizable Compound

The silicon atom-containing functional group possessed by the silicon atom-containing polymerizable compound is exemplified by trialkyl silyl group, chain-like siloxane structure, cyclic siloxane structure, and cage-like siloxane structure. From the viewpoints of compatibility with the other component and mold releasability, the functional group having a trimethylsilyl group or dimethylsiloxane structure is preferable.

The silicon atom-containing polymerizable compound is exemplified by those typically described in paragraph [0044] of JP-A-2012-072269, the contents of which are incorporated into this specification.

The polymerizable compound preferably contains a polymerizable compound having an alicyclic hydrocarbon group and/or aromatic group, and more preferably contains a polymerizable compound having an alicyclic hydrocarbon group and/or aromatic group, and a polymerizable compound having a silicon atom and/or fluorine atom. Of the whole polymerizable components contained in the curable composition for imprints of the present invention, the total content of the polymerizable compounds having an alicyclic hydrocarbon group and/or aromatic group preferably accounts for 30 to 100% by mass of the total polymerizable compounds, more preferably 50 to 100% by mass, and furthermore preferably 70 to 100% by mass.

In a further preferable embodiment, a (meth)acrylate polymerizable compound having an aromatic group, used as the polymerizable compound, preferably accounts for 50 to 100% by mass of the total polymerizable components, more preferably 70 to 100% by mass, and furthermore preferably 90 to 100% by mass.

In a particularly preferable embodiment, a polymerizable compound (1) described below accounts for 0 to 80% by mass (more preferably 20 to 70% by mass) of the total polymerizable components, a polymerizable compound (2) described below accounts for 20 to 100% by mass (more preferably 50 to 100% by mass) of the total polymerizable components, and a polymerizable compound (3) described below accounts for 0 to 10% by mass (more preferably 0.1 to 6% by mass) of the total polymerizable components:

(1) polymerizable compound having an aromatic group (preferably phenyl group or naphthyl group, and more preferably naphthyl group) and a (meth)acrylate group;

(2) polymerizable compound having an aromatic group (preferably phenyl group or naphthyl group, and more preferably phenyl group), and two (meth)acrylate groups; and

(3) polymerizable compound having at least either of a fluorine atom and silicon atom, and a (meth)acrylate group.

In the curable composition for imprints, content of the polymerizable compound having a viscosity at 25° C. of smaller than 5 mPa·s is preferably 50% by mass or less of the total polymerizable compounds, more preferably 30% by mass or less, and furthermore preferably 10% by mass or less. By adjusting the content in the ranges described above, ink-jetting stability may be improved, and thereby defects in transfer-by-imprint may be reduced.

Polymerization Initiator (D)

The curable composition for imprints used in the present invention contains a photo-polymerization initiator. The photo-polymerization initiator used in the present invention is arbitrarily selectable from those generating an active species capable of polymerizing the above-described polymerizable compounds under photo-irradiation. The photo-polymerization initiator is preferably a radical polymerization initiator or cation polymerization initiator, and more preferably a radical polymerization initiator. In the present invention, two or more species of the photo-polymerization initiator may be used in combination.

The content of the photo-polymerization initiator used in this invention is typically 0.01 to 15% by mass in the whole composition excluding the solvent, preferably 0.1 to 12% by mass, and more preferably 0.2 to 7% by mass. When two or more species of photo-polymerization initiators are used, the total amount falls in these ranges.

If the content of photo-polymerization initiator is 0.01% by mass or more, there will be tendencies that the sensitivity (rapid curability), resolution, line edge roughness and strength of coated film are advantageously improved. On the other hand, if the content of the photo-polymerization initiator is controlled to 15% by mass or less, there will be tendencies that the optical transparency, colorability and handleability are advantageously improved.

As the radical photo-polymerization initiator used in this invention, for example, commercially available initiators may be used. Examples of them preferably used are typically described in paragraph [0091] of JP-A-2008-105414. Among them, acetophenone-base compound, acylphosphine oxide-base compound, and oxime ester-base compound are preferable from the viewpoints of curing sensitivity and absorption characteristics.

The acetophenone-base compound is preferably exemplified by those typically described in paragraph [0101] of JP-A-2012-175017, the contents of which are incorporated into this specification.

Dialkoxy acetophenone-base compound is preferably exemplified by those typically described in paragraph [0101] of JP-A-2012-175017, the contents of which are incorporated into this specification.

Aminoacetophenone-base compound is preferably exemplified by those typically described in paragraph [0101] of JP-A-2012-175017, the contents of which are incorporated into this specification.

The acylphosphine oxide-base compound is preferably exemplified by those typically described in paragraph [0101] of JP-A-2012-175017, the contents of which are incorporated into this specification.

The oxime ester-base compound is preferably exemplified by those typically described in paragraph [0101] of JP-A-2012-175017, the contents of which are incorporated into this specification.

Cation photo-polymerization initiator used in this invention is exemplified by those typically described in paragraph [0101] of JP-A-2012-175017, the contents of which are incorporated into this specification.

It is preferable to use two or more species of the photo-polymerization initiators in combination. When two or more species are used in combination, it is preferable to combine two or more species of radical polymerization initiators. Specific examples of combination include Darocur (registered trademark) 1173 and Irgacure (registered trademark) 907; Darocur 1173 and Lucirin (registered trademark) TPO; Darocur 1173 and Irgacure (registered trademark) 819; Darocur 1173 and Irgacure (registered trademark) OXE01; Irgacure 907 and Lucirin TPO; and Irgacure 907 and Irgacure 819. By such combinations, the exposure margin may be expanded.

Ratio (ratio by mass) of photo-polymerization initiators used in combination is preferably 9:1 to 1:9, more preferably 8:2 to 2:8, and furthermore preferably 7:3 to 3:7.

In the present invention, “light” includes not only those in the wavelength regions of UV, near-UV, deep-UV, visible light and infrared, and other electromagnetic waves, but also radiation ray. The radiation ray includes microwave, electron beam, EUV and X-ray. Also laser light such as 248 nm excimer laser, 193 nm excimer laser, and 172 nm excimer laser are usable. These sorts of light may be monochromatic light obtained after being passed through an optical filter, or may be composite light composed of a plurality of light components with different wavelengths. The exposure may be a multiple exposure, and may be carried out over the whole area after the pattern is formed for the purpose of enhancing strength of the film and the etching resistance.

### Surfactant

The curable composition for imprints used in the present invention preferably contains a surfactant. Content of the surfactant used in the present invention is typically 0.001 to 5% by mass of the whole composition, preferably 0.002 to 4% by mass, and furthermore preferably 0.005 to 3% by mass. When two or more species of surfactant are used, the total content falls in the above-described ranges. If the content of the surfactant falls in the range from 0.001 to 5% by mass of the composition, an effect on uniformity of coating will be good, and degradation in mold transfer characteristics due to excessive surfactant will be less likely to occur.

The surfactant is preferably nonionic surfactant, preferably contains at least one of fluorine-containing surfactant, silicone-base surfactant and fluorosilicone-base surfactant, more preferably contains both of fluorine-containing surfactant and silicone-base surfactant, or, fluorosilicone-base surfactant, and most preferably contains fluorosilicone-base surfactant. The fluorine-containing surfactant and silicone-base surfactant are preferably nonionic surfactants.

The “fluorosilicone-base surfactant” means a surfactant having both features of fluorine-containing surfactant and silicone-base surfactant.

By using such surfactant, it now becomes possible to prevent coating failures such as striation or scaly pattern (nonuniform drying of resist film), which possibly occur when the photo-curable composition for imprints in this invention is coated over a silicon wafer for manufacturing semiconductor devices, or over a square glass panel for manufacturing liquid crystal devices, and over various films formed on the base, such as chromium film, molybdenum film, molybdenum alloy film, tantalum film, tantalum alloy film silicon nitride film, amorphous silicon film, indium oxide film doped with tin oxide (ITO) film, and tin oxide film. It also becomes possible to improve fluidity of the photo-curable composition for imprints used in this invention in mold cavity, to improve releasability between the mold and the resist, to improve adhesiveness between the resist and the base, and to reduce viscosity of the composition. In particular, the photo-curable composition for imprints used in this invention, added with the surfactant, may be remarkably improved in uniformity of coating, so that a good coatability may be obtained irrespective of base size, in the coating process using a spin coater or slit scan coater.

Preferable examples include nonionic fluorine-containing surfactant, nonionic silicone-base surfactant, and fluorosilicone-base surfactant, having been explained previously regarding the lower layer-forming composition usable in this invention.

### Compound Having Polyalkylene Glycol Structure

The photo-curable composition for imprints used in this invention preferably contains a compound having a polyalkylene glycol structure. The compound having a polyalkylene glycol structure means a non-polymerizable compound having at least hydroxy group at the terminal, or, having a polyalkylene glycol structure as a result of etherification of the hydroxy group, and has substantially no fluorine atom and no silicon atom. Now the non-polymerizable compound means a compound having no polymerizable group.

The polyalkylene structure possessed by the compound having a polyalkylene glycol structure is preferably a polyalkylene glycol structure which contains an alkylene group having 1 to 6 carbon atoms; more preferably a polyethylene glycol structure, polypropylene glycol structure, polybutylene glycol structure, or mixed structure thereof; furthermore preferably the polyethylene glycol structure, polypropylene glycol structure, or mixed structure thereof; and particularly the polypropylene glycol structure.

It is preferable that the compound having a polyalkylene glycol structure is configured by substantially the polyalkylene glycol structure only, except for the terminal substituent. “Substantially” now means that the content of constituent other than the polyalkylene glycol structure is 5% by mass or less of the total, and preferably 1% by mass or less. In this invention, it is preferable that a compound configured by substantially the polypropylene glycol structure only is contained as the compound having a polyalkylene glycol structure.

The polyalkylene glycol structure preferably has 3 to 1000 alkylene glycol constitutive units, more preferably 4 to 500 units, furthermore preferably 5 to 100 units, and most preferably 5 to 50 units.

The compound having a polyalkylene glycol structure preferably has a weight-average molecular weight (Mw) of 150 to 10000, more preferably 200 to 5000, furthermore preferably 500 to 4000, and much more preferably 600 to 3000.

“The compound having a polyalkylene glycol structure contains substantially no fluorine atom and no silicon atom” means, for example, that the total content of fluorine atom and silicon atom is 1% or less. It is preferable that no fluorine atom and no silicon atom are contained at all. By the absence of fluorine atom and silicon atom, the photo-curable composition for imprints will have an improved compatibility with the polymerizable compound, and in particular when configured as a solvent-free composition, will improve uniformity of coating, patternability in imprinting, and line edge roughness after dry etching.

The compound having a polyalkylene glycol structure preferably has at least one hydroxy group at the terminal, or etherified hydroxy group. If at least one hydroxy group resides at one terminal, or, the hydroxy group is etherified, the usable compound may have a hydroxy group at the residual terminal, or may have a terminal hydroxy group having the hydrogen atom thereof substituted. The group which may substitute the hydrogen atom of the terminal hydroxy group is preferably alkyl group (i.e., polyalkylene glycol alkyl ether), or acyl group (i.e., polyalkylene glycol ester). Polyalkylene glycol having hydroxy groups at all terminals is more preferable. While a compound configured by a plurality of (preferably 2 or 3) polyalkylene glycol chains combined by linking group(s) may preferably be used, the compound preferably has a straight-chain structure having no branching out from the polyalkylene glycol chain. In particular, diol-type polyalkylene glycol is preferable.

Preferable examples of the compound having a polyalkylene glycol structure include polyethylene glycol, polypropylene glycol; and mono- or dimethyl ether of them, mono- or dioctyl ether, mono- or dinonyl ether, mono- or didecyl ether, monostearyl ester, monooleyl ester, monoadipate ester, and monosuccinate ester of these compounds.

The content of the compound having a polyalkylene glycol structure is preferably 0.1 to 20% by mass in the whole photo-curable composition for imprints excluding solvent, more preferably 0.2 to 10% by mass, furthermore preferably 0.5 to 5% by mass, and most preferably 0.5 to 3% by mass.

### Antioxidant

Preferably, the curable composition for imprints used in the invention contains a known antioxidant. The content of the antioxidant to be in the composition is, for example, from 0.01 to 10% by mass of the total amount of the polymerizable monomers constituting the composition, preferably from 0.2 to 5% by mass. When two or more different types of antioxidants are in the composition, the total amount thereof falls within the above range.

The antioxidant is for preventing fading by heat or photoirradiation, and for preventing fading by various gases such as ozone, active hydrogen NOx, SOx (x is an integer), etc. Especially in the invention, the antioxidant added to the composition brings about the advantage that the cured film is prevented from being discolored and the film thickness is prevented from being reduced through decomposition. The antioxidant includes hydrazides, hindered amine-type antioxidants, nitrogen-containing heterocyclic mercapto compounds, thioether-type antioxidants, hindered phenol-type antioxidants, ascorbic acids, zinc sulfate, thiocyanates, thiourea derivatives, saccharides, nitrites, sulfites, thiosulfates, hydroxylamine derivatives, etc. Of those, preferred are hindered phenol-type antioxidants and thioether-type antioxidants from the viewpoint of their effect of preventing cured film discoloration and preventing film thickness reduction.

Commercial products of the antioxidant usable herein include Irganox 1010, 1035, 1076, 1222 (all by BASF GmbH); Antigene P, 3C, FR, Sumilizer S, Sumilizer GA80 (by Sumitomo Chemical); Adekastab A070, A080, A0503 (by Adeka), etc. These may be used either singly or as combined.

### Polymerization Inhibitor

Furthermore, the curable composition for imprints used in the invention preferably comprises a polymerization inhibitor. The content of the polymerization inhibitor is from 0.001 to 1% by mass, more preferably from 0.005 to 0.5% by mass, and even more preferably from 0.008 to 0.05% by mass, relative to all the polymerizable monomers, and the change in the viscosities over time can be inhibited while maintaining a high curing sensitivity by blending the polymerization inhibitor in an appropriate amount. The polymerization inhibitor may be added at the production of the polymerizable monomer or may be added the curable composition for imprints after the production of the polymerizable monomer.

### Solvent

A solvent may be used for the curable composition for imprints used in the invention, in accordance with various needs. In particular, when a pattern having a thickness of at most 500 nm is formed, the composition preferably contains a solvent. Preferably, the solvent has a boiling point at normal pressure of from 80 to 200° C. Regarding the type of the solvent, any solvent capable of dissolving the composition may be used. Preferred are solvents having at least any one of an ester structure, a ketone structure, a hydroxyl group and an ether structure. Concretely, the solvent is preferably one or more selected from propylene glycol monomethyl ether acetate, cyclohexanone, 2-heptanone, gamma-butyrolactone, propylene glycol monomethyl ether, ethyl lactate. Most preferred is a solvent containing propylene glycol monomethyl ether acetate as securing coating uniformity.

The content of the solvent in the composition for imprints used in the present invention may be suitably optimized depending on the viscosity of the constitutive ingredients except the solvent, the coatability of the composition and the intended thickness of the film to be formed. From the viewpoint of the coatability, the solvent content is preferably from 0 to 99% by mass of the composition. When the composition for imprints used in the present invention is applied onto the substrate by inkjet method, it is preferred that the composition does not substantially contain a solvent (for example 3% by mass or less, preferably 1% by mas or less). On the other hand, when a pattern having a film thickness of 500 nm or less is formed by spin-coating method or the like, the content may be 20 to 99% by mass, preferably 40 to 99% by mass, specifically preferably 70 to 98% by mass.

### Polymer Ingredient

The curable composition for imprints used in the invention may contain a poly-functional oligomer having a larger molecular weight than that of the above-mentioned, other poly-functional monomer within a range capable of attaining the object of the invention, for the purpose of further increasing the crosslinking density of the composition. Examples of the photoradical-polymerizable poly-functional oligomer include various acrylate oligomers such as polyester acrylates, urethane acrylates, polyether acrylates, epoxy acrylates. The amount of the oligomer ingredient to be added to the composition may be preferably from 0 to 30% by mass of the composition except the solvent therein, more preferably from 0 to 20% by mass, even more preferably from 0 to 10% by mass, most preferably from 0 to 5% by mass.

The curable composition for imprints for imprints used in the present invention may further contain a polymer component, in view of improving the dry etching resistance, imprint suitability and curability. The polymer component preferably has a polymerizable functional group in the side chain thereof. Weight-average molecular weight of the polymer component is preferably 2,000 to 100,000, and more preferably 5,000 to 50,000, in view of compatibility with the polymerizable monomer. Amount of addition of the polymer component, with respect to portion of the composition excluding the solvent, is preferably 0 to 30% by mass, more preferably 0 to 20% by mass, and most preferably 2% by mass or less. Pattern formability may be improved by adjusting the content of polymer component having a molecular weight of 2,000 or larger, with respect to the portion of the curable composition for imprints of the present invention excluding the solvent. From the viewpoint of pattern formability, as least as possible amount of resin component is preferable, and therefore the curable composition preferably contains no polymer component other than those composing the surfactant or trace amounts of additives.

In addition to the above-mentioned ingredients, the curable composition for imprints used in the invention may contain, if desired, UV absorbent, light stabilizer, antiaging agent, plasticizer, adhesion promoter, thermal polymerization initiator, colorant, elastomer particles, photoacid enhancer, photobase generator, basic compound, flowability promoter, defoaming agent, dispersant, etc.

The curable composition for imprints of the present invention may be prepared by mixing the individual components described in the above. Mixing and dissolution are generally proceeded in the temperature range from 0 to 100° C.

The curable composition prepared by mixing the individual components is preferably filtered, typically through a filter with a pore size of 0.003 μm to 5.0 μm, and more preferably 0.01 to 1.0 μm. The filtration may be proceeded in a multi-stage manner, or may be repeated a large number of times. The filtrate may be re-filtered. Material for composing a filter used for filtration may be polyethylene resin, polypropylene resin, fluorine-containing resin, nylon resin or the like, but not specifically limited.

In the curable composition for imprints used in the present invention, a mixture of the total components excluding the solvent preferably has a viscosity of 100 mPa·s or smaller, more preferably 1 to 70 mPa·s, furthermore preferably 2 to 50 mPa·s, and most preferably 3 to 30 mPa·s.

The curable composition for imprints used in the present invention after manufacturing is bottled in containers such as gallon bottles or coated bottles, and transported or stored. In this case, the inner space of the containers may be replaced with an inert gas such as nitrogen or argon, for the purpose of preventing deterioration. While the curable composition for imprints may be transported or stored at normal temperature, it is also preferable to control the temperature in the range from −20° C. to 0° C. for the purpose of preventing denaturation. Of course, the curable composition for imprints may be shielded from light up to a level of suppressing the reaction from proceeding.

In permanent films (resists for structural members) for use in liquid-crystal displays (LCD) and in resists for use for substrate processing for electronic materials, the resist is preferably prevented from being contaminated as much as possible with metallic or organic ionic impurities in order that the resist does not interfere with the performance of the products. Accordingly, the concentration of the metallic or organic ionic impurities in the curable composition for imprints of the invention is preferably at most 1 ppm, more preferably at most 100 ppb, even more preferably at most 10 ppb.

Method of Applying Photo-Curable Composition for Imprints onto Adhesive Film

Method of applying the photo-curable composition for imprints in this invention may be any of known methods. In this invention, coating film or liquid droplets may be applied, for example, by dip coating, air knife coating, curtain coating, wire bar coating, gravure coating, extrusion coating, spin coating, slit scanning, or ink jet process.

While the thickness of the pattern-forming layer composed of the photo-curable composition for imprints used in this invention may vary depending on the intended applications, it is preferably controlled to 0.03 to 30 μm or around. The photo-curable composition for imprints may be coated by multiple coating. In the ink jet process or the like, by which liquid droplets are placed on the adhesive film, the volume of liquid droplet is preferably 1 to 20 pl or around. The liquid droplets are preferably placed on the adhesive film while being spaced from each other.

In the step of curing the photo-curable composition for imprints, in order to imprint a pattern on the pattern-forming layer, light is made incident on the photo-curable composition for imprints and the adhesive film, while holding them between the base and a mold. In this way, a fine pattern preliminarily formed on a stamping surface of the mold may be imprinted on the pattern-forming layer. Alternatively, the photo-curable composition for imprints may be coated over the patterned mold, and the adhesive film may be pressed against it.

The mold material usable in the invention is described. In the photoimprint lithography with the composition for imprints of the invention, a light-transmissive material is selected for at least one of the mold material and/or the substrate. In the photoimprint lithography applied to the invention, the curable composition for imprints of the invention is applied onto a substrate to form a patterning layer thereon, and a light-transmissive mold is pressed against the surface of the layer, then this is irradiated with light from the back of the mold and the patterning layer is thereby cured. Alternatively, the curable composition for photoimprints is applied onto a light-transmissive substrate, then a mold is pressed against it, and this is irradiated with light from the back of the substrate whereby the curable composition for photoimprints can be cured.

The photoirradiation may be attained while the mold is kept in contact with the layer or after the mold is released. In the invention, preferably, the photoirradiation is attained while the mold is kept in contact with the patterning layer.

The mold usable in the present invention has a pattern to be transferred. The pattern on the mold may be formed with a desired level of processing accuracy, typically by photolithography, electron beam lithography and so forth. Methods of forming the pattern on the mold is not specifically limited in the present invention.

Not specifically defined, the light-transmissive mold material for use in the invention may be any one having a desired strength and durability. Concretely, its examples include glass, quartz, light-transparent resin such as PMMA or polycarbonate resin, transparent metal deposition film, flexible film of polydimethylsiloxane or the like, photocured film, metal film, etc.

The non-light-transmissive mold to be used in the invention where a light-transmissive substrate is used is not also specifically defined and may be any one having a predetermined strength. Concretely, examples of the mold material include ceramic material, deposition film, magnetic film, reflective film, metal material of Ni, Cu, Cr, Fe or the like, as well as SiC, silicon, silicon nitride, polysilicon, silicon oxide, amorphous silicon, etc. However, these are not limitative. The shape of the mold is not also specifically defined, and may be any of a tabular mold or a roll mold. The roll mold is used especially when continuous transfer in patterning is desired.

In photoimprint lithography with the curable composition for imprints, in general, the mold pressure in the patterning method of the invention is preferably at most 10 atmospheres. When the mold pressure is at most 10 atmospheres, then the mold and the substrate are hardly deformed and the patterning accuracy tends to increase. It is also favorable since the pressure unit may be small-sized since the pressure to be given to the mold may be low. The mold pressure is preferably selected from the region capable of securing the mold transfer uniformity, within a range within which the residual film of the curable composition for imprints in the area of mold pattern projections may be reduced.

The dose of photoirradiation in the step of irradiating the patterning layer with light may be sufficiently larger than the dose necessary for curing. The dose necessary for curing may be suitably determined depending on the degree of consumption of the unsaturated bonds in the curable composition for imprints and on the tackiness of the cured film as previously determined.

In the imprint lithography applied to the present invention, photo-irradiation is conducted while keeping the substrate temperature generally at room temperature, wherein the photo-irradiation may alternatively be conducted under heating for the purpose of enhancing the reactivity. Also photo-irradiation in vacuo is preferable, since a vacuum conditioning prior to the photo-irradiation is effective for preventing entrainment of bubbles, suppressing the reactivity from being reduced due to incorporation of oxygen, and for improving the adhesiveness between the mold and the curable composition for imprints. In the method for forming a pattern according to the present invention, the degree of vacuum in the process of photo-irradiation is preferably in the range from 10⁻¹ Pa to normal pressure.

Light to be used for photoirradiation to cure the curable composition for imprints of the invention is not specifically defined. For example, it includes light and irradiations with a wavelength falling within a range of high-energy ionizing radiation, near-ultraviolet, far-ultraviolet, visible, infrared, etc. The high-energy ionizing radiation source includes, for example, accelerators such as Cockcroft accelerator, Handegraf accelerator, linear accelerator, betatoron, cyclotron, etc. The electron beams accelerated by such an accelerator are used most conveniently and most economically; but also are any other radioisotopes and other radiations from nuclear reactors, such as yrays, X rays, a rays, neutron beams, proton beams, etc. The UV sources include, for example, UV fluorescent lamp, low-pressure mercury lamp, high-pressure mercury lamp, ultra-high-pressure mercury lamp, xenon lamp, carbon arc lamp, solar lamp, etc. The radiations include microwaves, EUV, etc. In addition, laser rays for use in microprocessing of semiconductors, such as LED, semiconductor laser ray, 248 nm KrF excimer laser ray, 193 nm ArF excimer laser ray and others, are also favorably used in the invention. These lights may be monochromatic lights, or may also be lights of different wavelengths (mixed lights).

In the exposure, the illuminance is preferably controlled in the range from 1 to 50 mW/cm². With the illuminance controlled to 1 mW/cm² or above, the exposure time may be shortened to improve the productivity, meanwhile with the illuminance controlled to 50 mW/cm² or below, characteristics of the permanent film will be more likely to be suppressed from degrading due to side reaction, which is advantageous. The luminous exposure is preferably controlled in the range from 5 to 1000 mJ/cm². With the luminous exposure controlled to 5 mJ/cm² or above, the photo-curing will thoroughly proceed without narrowing the exposure margin, and adhesion of unreacted components onto the mold will be less likely to occur. On the other hand, by controlling the luminous exposure to 1000 mJ/cm² or below, the photo-curable composition for imprints may be suppressed from decomposing.

In the exposure, it is also preferable to control the oxygen concentration below 100 mg/L, by feeding an inert gas such as nitrogen or argon, in order to avoid oxygen-induced inhibition of radical polymerization.

In the patterning method of the invention, after the pattern layer (a layer comprising the curable composition for imprints layer) is cured through photoirradiation, if desired, the cured pattern may be further cured under heat given thereto. The method may additionally includes the post-curing step. Thermal curing of the composition of the invention after photoirradiation is preferably attained at 150 to 280° C., more preferably at 200 to 250° C. The heating time is preferably from 5 to 60 minutes, more preferably from 15 to 45 minutes.

### Fine Pattern

A fine pattern formed by the method for forming a pattern of this invention, composed of the base, the adhesive film and the photo-curable composition for imprints, may be used as a permanent film (resist material for structural members) typically for liquid crystal display (LCD), or an etching resist.

The pattern formed using the photo-curable composition in this invention also has a good solvent resistance. While the photo-curable composition in this invention preferably shows high resistance against a variety of solvents, it is particularly preferable that the thickness of the film does not change if, for example, immersed in N-metylpyrrolidone, a solvent used in the general process of manufacturing of substrate, at 25° C. for 10 minutes.

The pattern formed by the method for forming a pattern of this invention is also usable as an etching resist. When the photo-curable composition in this invention is used as the etching resist, first, by using a silicon wafer or the like as the base, having formed thereon a SiO₂ film or the like, a fine nanometer-sized pattern is formed on the base according to the method for forming a pattern of this invention. A desired pattern may be formed on the base by wet etching using hydrofluoric acid, or by dry etching using an etching gas such as CF₄. The photo-curable composition of this invention preferably has a high etching resistance against dry etching using fluorocarbon or the like.

### [Method for Manufacturing Semiconductor Device]

The method for manufacturing a semiconductor device of this invention is characterized by using the above-described fine pattern as an etching mask. By using the above-described fine pattern as the etching mask, the base is processed. For example, the base is dry-etched while using the fine pattern as the etching mask, to thereby selectively remove the upper surface portion of the base. By repeating such treatment on the base, a semiconductor device may be obtained. The semiconductor device is typically an LSI (large scale integrated circuit).

### EXAMPLE

This invention will further be detailed referring to Examples. Materials, amounts of consumption, ratios, details of processes, and procedures of processes described in Examples below may be modified suitably, without departing from the spirit of this invention. The scope of this invention is therefore by no means interpreted limitatively by Examples described below.

In Examples in this application, each of the compounds listed in Table below were mixed according to each ratio of mixing again listed in Table below, and dissolved in propylene glycol methyl ether acetate to prepare a 0.1% by mass solution. The solution was filtered through a 0.1-μm polytetrafluoroethylene filter to obtain a lower film-forming composition.

TABLE 1

| Poly- | |
|---|---|
| merizable | |
| compound | |
| (A) | |
| A1 | 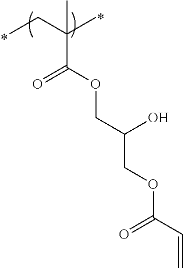 |
| A2 | 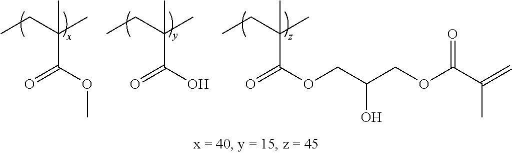 |
| A3 | 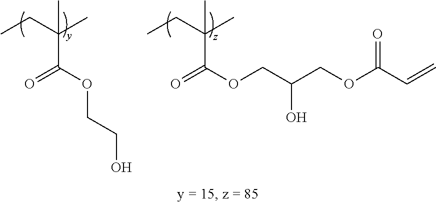 |
| A4 | 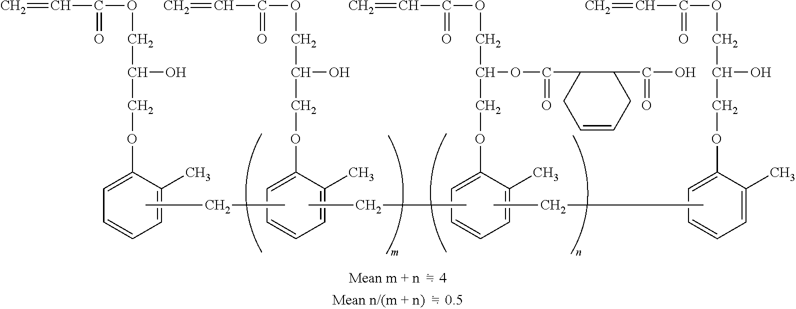 |
| A5 | 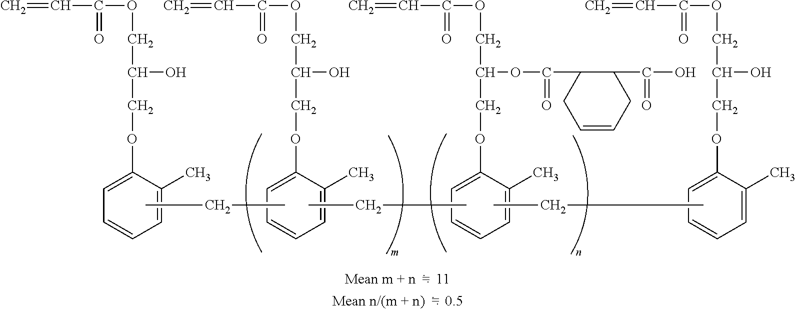 |
| A6 | 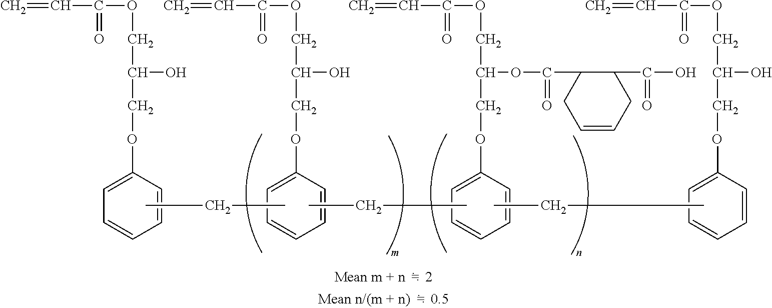 |
| A7 | 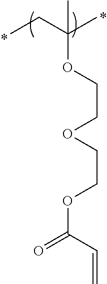 |

| Polymerizable | | |
|---|---|---|
| compound | | |
| (A) | Molecular weight | Route |
| A1 | About 7500 | Synthetic compound |
| A2 | About 14000 | Synthetic compound |
| A3 | About 18000 | Synthetic compound |
| A4 | About 2000 | NK Oligo EA-7140/PGMAc |
| | | manufactured from |
| | | Shin-Nakamura Chemical Co., Ltd. |
| A5 | About 4500 | NK Oligo EA-7440/PGMAc |
| | | manufactured from |
| | | Shin-Nakamura Chemical Co., Ltd. |
| A6 | About 1400 | NK Oligo EA-6340/PGMAc |
| | | manufactured from |
| | | Shin-Nakamura Chemical Co., Ltd. |
| A7 | About 21000 | PVEEA |
| | | manufactured from |
| | | NIPPON SHOKUBAI CO., LTD. |

### Exemplary Syntheses

### Synthesis of A2

Into a flask, 100 g of propylene glycol monomethyl ether acetate (PGMEA) as a solvent was placed, and heated to 90° C. under a nitrogen atmosphere. To the solution, a mixed solution containing 16.0 g (0.16 mol) of methyl methacrylate (MMA) (from Wako Pure Chemical Industries, Ltd.), 20.7 g (0.24 mol) of methacrylic acid (MAA) (from from Wako Pure Chemical Industries, Ltd.), 2.8 g (12 mmol) of 2,2′-azobis(methyl 2-methylpropanate) (V-601) (from Wako Pure Chemical Industries, Ltd.), and 50 g of PGMEA, was added dropwise over 2 hours. After completion of the dropwise addition, the mixture was further stirred at 90° C. for 4 hours, to obtain a MMA/MAA copolymer.

To the solution of MMA/MAA copolymer, 25.6 g (0.12 mol) of glycidyl methacrylate (GMA) (from Wako Pure Chemical Industries, Ltd.), 2.1 g of tetraethylammonium bromide (TEAB) (from Wako Pure Chemical Industries, Ltd.), and 50 mg of 4-hydroxy-tetramethylpiperidine 1-oxyl (4-HO-TEMPO) (from Wako Pure Chemical Industries, Ltd.) were added, and the mixture was allowed to react at 90° C. for 8 hours. After confirming by ¹H-NMR that GMA was consumed up by the reaction, a PGMEA solution of resin U-1 was obtained. From gel permeation chromatography (GPC), the thus obtained U-1 was found to have a weight-average molecular weight (Mw, polystyrene equivalent) of 14000, and a dispersion (Mw/Mn) of 2.2.

### Synthesis of A1, Synthesis of A3

Resins A1 and A3 were synthesized according to the above-described exemplary synthesis of resin A2. In Table below, HEMA stands for benzyl methacrylate (from Wako Pure Chemical Industries, Ltd.). Table below also summarizes molar ratio of source resins used in this Example and weight-average molecular weight (Mw). In table below, the notation of GMA-AA means that GMA is a source material for composing the principal chain, and a group derived from AA (acrylic acid) is bound as the side chain.

TABLE 2

| | HEMA | GMA-AA | Mw |
|---|---|---|---|
| A-1 | 0 | 100 | 17000 |
| A-3 | 15 | 85 | 18000 |

TABLE 3

| | | Molecular | |
|---|---|---|---|
| | Crosslinking agent | Weight | Route |
| K1 | Methyl etherified | About 390 | Cymel 303ULF manufactured |
| | melamine resin | | from Cytec Industries |
| | | | Inc. |

TABLE 4

| | Catalyst | Molecular weight | Route |
|---|---|---|---|
| S1 | p-toluene sulfonate | About 170 | Cycat4040 |
| | | | manufactured |
| | | | from Cytec |
| | | | Industries |
| | | | Inc. |

TABLE 5

| | | A1 | A2 | A3 | A4 | A5 | A6 | A7 | K1 | S1 |
|---|---|---|---|---|---|---|---|---|---|---|
| Under | 1 | 100 | | | | | | | | |
| layer | 2 | | 100 | | | | | | | |
| Film | 3 | | | 100 | | | | | | |
| | 4 | | | | 79 | | | | 20 | 1 |
| | 5 | | | | | 79 | | | 20 | 1 |
| | 6 | | | | | | 79 | | 20 | 1 |
| | 7 | | | | | | | 100 | | |

In the above table, the unit is parts by mass.

### [Photo-Curable Composition for Imprints]

Polymerizable monomers, a polymerization initiator and additives listed in Table below were mixed, and the mixture was further added with 200 ppm (0.02% by mass), relative to the polymerizable monomer(s), of 4-hydroxy-2,2,6,6-tetramethylpiperidine-1-oxyl, free radical (from. Tokyo Chemical Industry Co., Ltd.) as a polymerization inhibitor. The mixture was filtered through a 0.1-μm polytetrafluoroethylene, to prepare photo-curable compositions for imprints. The numerals in Table are given in ratio by mass.

TABLE 6

| | NIL1 | NIL2 |
|---|---|---|
| R-1 | | 50 |
| R-2 | 100 | 49.5 |
| R-3 | | 0.5 |
| P-1 | 3 | 3 |
| X1 | 1 | |
| X2 | 2 | 2 |

### [Polymerizable Monomer]

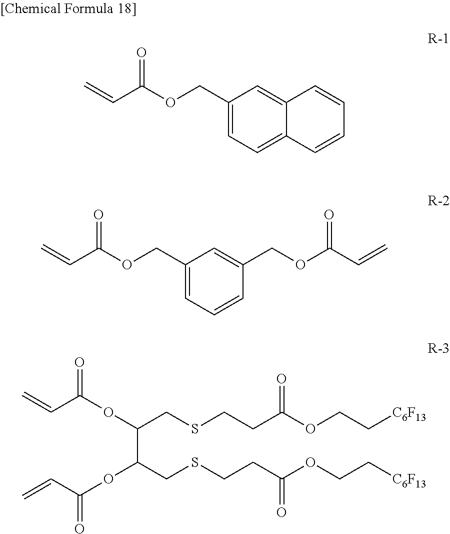

TABLE 7

| | |
|---|---|
| R-1 | Synthesized through a routine method from |
| | 2-bromomethylnaphatele and acrylic acid. |
| R-2 | Synthesized through a routine method from α, |
| | α′-dichloro-m-xylene and acrylic acid. |
| R-3 | Synthesized by the method disclosed in JP-A-2010-239121. |

### Photo-Polymerization Initiator

### P-1: (2-dimethylamino-2-(4-methylbenzyl)-1-(4-morpholine-4-ylphenyl)butane-1-one (from BASF, Irgacure 379EG)

### [Additives]

X1: PF-636 (from Omnova Solutions Inc., fluorine-containing surfactant)
X2: polypropylene glycol (from Wako Pure Chemical Industries, Ltd.)

### [Nano-Imprinting]

A quartz mold having a rectangular line/space pattern (1/1), with a line width of 60 nm, and a trench depth of 100 nm, was used as a mold.

Over the surface of a silicon wafer, 4 mL of each of the thus obtained adhesive compositions was spin-coated. Rinsing was carried out one minute after the adhesive composition was coated over the surface. Next, the thus coated adhesive composition was rinsed by spin coating process. In specific procedures of rinsing by the spin coating process, first, 2 mL of solvent (propylene glycol monomethyl ether acetate (PGMEA) or ethyl lactate (EL)) was dropped on the adhesive composition, and the silicon wafer was spun at 100 rpm for one second. Then the silicon wafer was spun at 5000 rpm for 5 seconds. Lastly the silicon wafer was spun at 1500 rpm for 30 seconds. After the rinsing, the adhesive composition was dried at 220° C. for 60 seconds on a hot plate, to obtain an adhesive film. These processes were carried out at 23° C. (room temperature, during spin coating and rinsing).

On the thus obtained adhesive film, the photo-curable composition for imprints were discharged using an ink jet printer DMP-2831 from Fujifilm-Dimatix Inc., used as the ink jet apparatus, at a droplet volume of 1 pl per nozzle, while controlling the time of discharge so as to arrange liquid droplets at approximately 100 μm pitch to form a square matrix, which corresponds to a thickness of the obtainable patterned residual film. of 10 nm. In this process, the temperature of the curable composition to be discharged was controlled to 25° C. A mold was placed thereon under a nitrogen gas flow so as to fill the mold with the photo-curable composition, exposed with light from the mold side using a mercury lamp at 300 mJ/cm², and released after the exposure. A pattern was thus obtained.

### [Process of Substrate]

The pattern-forming article, having formed thereon the resist layer with an imprinted irregularity pattern, was dry-etched by argon ion milling process (ICP etching apparatus NE-550, from ULVAC Inc.), using the resist layer for imprints having the irregularity pattern imprinted thereon as a mask, while cooling the substrate from the back to 10° C., and thereby an irregularity pattern conforming to the irregularity pattern formed in the resist layer was etched into the substrate.

The surface of the pattern-forming article having the irregularity pattern formed thereon was then processed by oxygen ashing, followed by UV treatment, to remove the resist layer remained after processing of the substrate.

### [Evaluation of Film Thickness]

The substrate having the adhesive film formed thereon, and before being subjected to nano-imprinting, was measured using an ellipsometer DVA-36L, from Mizojiri Optical Co., Ltd., to determine the thickness of the adhesive film.

### [Evaluation of Surface Profile]

The substrate having the adhesive film formed thereon, and before being subjected to nano-imprinting was observed under an AFM (atomic force microscope), to determine the surface roughness Ra of the adhesive film.

### [Evaluation of Pattern Profile]

A top view of the pattern obtained after the processing of the substrate was observed under a critical-dimension scanning electron microscope (SEM) (from JEOL Ltd.), to evaluate the roughness. Also a cross section was concurrently observed under a SEM, to evaluate the pattern height. Pattern profile of the substrate after processed as described above was subjected to a sensory evaluation, and ranked on a four-grade evaluation scale shown below:

A: difference between the height of projection and target height L is smaller than ±5%, and the roughness is not larger than the roughness of the mold;

B: difference between the height of projection and target height L is ±5 or larger and 10% or smaller, or the roughness is larger than the roughness of the mold and smaller than +1 nm;

C: difference between the height of projection and target height exceeds ±10% and 15% or smaller, or the roughness is 1 to 2 nm larger than the roughness of the mold; and

D: difference between the height of projection and target height exceeds ±15%, or the roughness is 2 nm or above larger than the toughness of the mold.

### [Evaluation of Adhesion Strength]

Each of the lower film listed in Table below was formed respectively over the surface of a silicon wafer and the surface of a quartz wafer. On the lower film provided over the silicon wafer, the photo-curable composition for imprints was discharged by the same method as described above in [Nano-Imprinting], the quartz wafer was then placed thereon so that the lower film side thereof is brought into contact with the layer of the photo-curable composition for imprints, and irradiated with light from the quartz wafer side using a high-pressure mercury lamp at 300 mJ/cm². After the exposure, the releasing force required for removing the quartz wafer was measured. The releasing force corresponds to the adhesive force between the silicon wafer and the photo-curable composition for imprints.

The releasing force was measured referring to paragraphs [0102] to [0107] of JP-A-2011-206977, and according to a method described in Comparative Example. More specifically, the releasing force was measured according to releasing steps 1 to 6 and 16 to 18 illustrated in FIG. 5 of the same patent literature. Results of measurement of the releasing force were evaluated according to the criteria below.

an adhesive force≧30 N
b: adhesive force<30 N

TABLE 8

| | Coating | | | | | | | |
|---|---|---|---|---|---|---|---|---|
| | method of | | | | Film | | | |
| | adhesive | | | Adhesive | thickness | Ra | Pattern | Adhesion |
| | composition | Rinsing (Solvent) | Bake | Film | (nm) | (nm) | Profile | Strength |
| Example 1 | Spin coating | Spin rinse (PGMEA) | 220° C. 60 sec | 1 | 0.5 | 0.2 | A | a |
| Example 2 | Spin coating | Spin rinse (PGMEA) | 220° C. 60 sec | 2 | 0.5 | 0.2 | A | a |
| Example 3 | Spin coating | Spin rinse (PGMEA) | 220° C. 60 sec | 3 | 0.5 | 0.2 | A | a |
| Example 4 | Spin coating | Spin rinse (PGMEA) | 220° C. 60 sec | 4 | 1.2 | 0.6 | B | a |
| Example 5 | Spin coating | Spin rinse (PGMEA) | 180° C. 60 sec | 5 | 1.2 | 0.6 | B | a |
| Example 6 | Spin coating | Spin rinse (PGMEA) | 180° C. 60 sec | 6 | 1.2 | 0.6 | B | a |
| Example 7 | Spin coating | Spin rinse (PGMEA) | 220° C. 60 sec | 7 | 0.01 | 0.2 | C | b |
| Example 8 | Spin coating | Spin rinse | 220° C. 60 sec | 1 | 0.5 | 0.1 | A | a |
| | | (Vertrel after | | | | | | |
| | | PGMEA) | | | | | | |
| Example 9 | Spin coating | Spin rins (EL) | 220° C. 60 sec | 1 | 0.5 | 0.3 | A | a |
| Example 10 | Spin coating | Spin rinse (Acetone) | 220° C. 60 sec | 1 | 0.5 | 0.6 | B | a |
| Example 11 | Spin coating | Spin rinse (PGMEA) | not doing | 1 | 0.5 | 0.2 | A | b |
| Comparative | Spin coating | not doing | 220° C. 60 sec | 1 | 1.5 | 0.7 | D | a |
| Example 1 | | | | | | | | |
| Comparative | Spin coating | not doing | 220° C. 60 sec | 7 | 1.5 | 0.7 | D | a |
| Example 2 | | | | | | | | |

While all results of evaluation shown above were obtained when the photo-curable composition for imprints NIL1 was used, similar tendencies were observed also when the photo-curable composition for imprints NIL2 were used.

As clearly understood from Table above, by using the adhesive film obtained by the method for manufacturing an adhesive film of this invention, patterns capable of yielding good pattern profile after etching were obtained. In addition, by using the adhesive film formed by the method for manufacturing an adhesive film of this invention, the photo-curable composition for imprints was found to show good adhesive force to the base.

In contrast, when the adhesive film of this invention was not used, as seen in Comparative Examples, the pattern profile obtained after etching was found to be poor.

### DESCRIPTIONS OF SIGNS

1 substrate
2 adhesive film
3 curable composition for imprints
4 mold

What is claimed is:

1. A method for manufacturing an adhesive film for imprints, the method comprising applying an adhesive composition for imprints in a base, and then rinsing the adhesive composition for imprints;
wherein the adhesive composition for imprints contains a polymerizable compound having a molecular weight of at most 1,000.

2. The method for manufacturing an adhesive film for imprints of claim 1, wherein the rinsing is followed by baking.

3. The method for manufacturing an adhesive film for imprints of claim 1, wherein the rinsing is effected by spin coating.

4. The method for manufacturing an adhesive film for imprints of claim 3, wherein, assuming a time range between a start and an end of rinsing as T, the base is spun at a smaller number of rotation (rpm) in a time range up to 0.005T to 0.3T after the start of rinsing, than in a time range 0.6T up to 0.95T before the end of rinsing.

5. The method for manufacturing an adhesive film for imprints of claim 1, wherein the rinsing is conducted using a solvent having a boiling point of 50 to 180° C.

6. The method for manufacturing an adhesive film for imprints of claim 1, wherein the rinsing is conducted using propylene glycol monomethyl ether acetate.

7. The method for manufacturing an adhesive film for imprints of claim 1, wherein the rinsing is started within one hour after the adhesive composition for imprints is applied in the base.

8. The method for manufacturing an adhesive film for imprints of claim 1, wherein the adhesive composition for imprints contains a solvent.

9. The method for manufacturing an adhesive film for imprints of claim 1, wherein the polymerizable compound contained in the adhesive composition for imprints has a hydroxy group or carboxyl group.

10. The method for manufacturing an adhesive film for imprints of claim 1, wherein the base has a rectangular shape.

11. The method for manufacturing an adhesive film for imprints of claim 1, wherein the base has a surface energy of smaller than 60 mJ/m².

12. The method for manufacturing an adhesive film for imprints of claim 1, wherein the adhesive composition for imprints is applied in the base by spin coating.

13. The method for manufacturing an adhesive film for imprints of claim 4, wherein the rinsing is conducted using a solvent having a boiling point of 50 to 180° C.

14. The method for manufacturing an adhesive film for imprints of claim 4, wherein the rinsing is started within one hour after the adhesive composition for imprints is applied in the base.

15. An adhesive film for imprints having a thickness smaller than 1.3 nm.

16. An adhesive film for imprints, which is obtainable by a method for manufacturing an adhesive film for imprints described in claim 1 and has a thickness smaller than 1.3 nm.

17. The adhesive film for imprints of claim 15, having a surface roughness Ra of 0.6 nm or smaller.

18. A method for forming a pattern, the method comprising:
forming an adhesive film for imprints in a base, by a method for manufacturing an adhesive film for imprints of claim 1;
applying a photo-curable composition for imprints on a surface of the adhesive film for imprints;
irradiating light on the photo-curable composition for imprints and the adhesive film for imprints, while holding the photo-curable composition for imprints and the adhesive film for imprints between the base and a mold with a fine pattern, to thereby cure the photo-curable composition for imprints; and
releasing the mold.

19. A method for manufacturing a semiconductor device comprising a method for forming a pattern of claim 18.

20. A semiconductor device manufactured by a method for manufacturing a semiconductor device described in claim 19.
